(19) United States
(12) Patent Application Publication
(10) Pub. No.: US 2009/0214960 A1
(43) Pub. Date: Aug. 27, 2009

(54) RESIST COMPOSITION AND PATTERNING PROCESS

(75) Inventors: Takanobu Takeda, Joetsu-shi (JP); Akinobu Tanaka, Joetsu-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: SHIN-ETSU CHEMICAL CO., LTD., Tokyo (JP)

(21) Appl. No.: 12/389,515

(22) Filed: Feb. 20, 2009

(30) Foreign Application Priority Data
Feb. 21, 2008 (JP) 2008-039730

(51) Int. Cl. G03F 1/00; G03F 7/004; G03F 7/20

(52) U.S. Cl. 430/5; 430/270.1; 430/326

(57) ABSTRACT

In a chemically amplified resist composition comprising a base resin, an acid generator, and a solvent, 1400-5000 pbw of the solvent is present per 100 pbw of the resin. The solvent comprises a major proportion of PGMEA, 10-40 wt % of ethyl lactate, a total of PGMEA and ethyl lactate being at least 60 wt %, and 0.2-20 wt % of a high-boiling solvent.

### CROSS-REFERENCE TO RELATED APPLICATION

This non-provisional application claims priority under 35 U.S.C. §119(a) on Patent Application No. 2008-039730 filed in Japan on Feb. 21, 2008, the entire contents of which are hereby incorporated by reference.

### TECHNICAL FIELD

This invention relates to a resist composition having advantages of line edge roughness (LER), resolution and shelf stability, and a patterning process using the same.

### BACKGROUND ART

A number of efforts are currently made to achieve a finer pattern rule in the drive for higher integration and operating speeds in LSI devices. Deep-ultraviolet lithography using KrF or ArF excimer laser has become the main stream of microfabrication technology. The deep-UV lithography combined with chemically amplified resist is capable of patterning to a feature size of 0.2 μm or less while pattern processing to a feature size of less than 0.065 μm now becomes the target. Also in the electron beam (EB) lithography, the progress of chemically amplified resist has reached a practically acceptable sensitivity to EB of higher energy, indicating possible processing to a finer size. Further in the lithography using EUV, use of chemically amplified resist is thought essential to achieve a practically acceptable sensitivity.

In the course of development of such chemically amplified positive resist compositions, the addition and modification of various resist components have been proposed in order to ameliorate the outstanding problems of resolution, sensitivity, pattern profile, post-exposure delay (PED, a change of pattern profile with standing time following exposure) and substrate dependency. Among others, the solvent is an important component to impart a uniform coating capability to coating compositions including chemically amplified resist compositions. A variety of solvents have been proposed to enable effective resist coating. An ability to form a uniform coating is indispensable to improve line edge roughness (LER) and resolution. To attain the goals of homogeneous dissolution of resist components and deposition of a uniform coating at the same time, a mixture of solvents is generally used rather than individual solvents.

One exemplary solvent mixture is proposed in Patent Document 1 as comprising propylene glycol monoalkyl ether acetate and propylene glycol monoalkyl ether. This solvent mixture is useful in inhibiting formation of defects in the resist film and becomes effective when a proportion of propylene glycol monoalkyl ether exceeds 50% by weight based on the total solvent weight.

Another solvent mixture which is effective for improving LER is proposed in Patent Document 2 as comprising propylene glycol monoalkyl ether acetate, propylene glycol monoalkyl ether and optionally, γ-butyrolactone. Allegedly a choice of this solvent mixture overcomes the problem of micro-grains (granular foreign matter of 100 μm or smaller) during development.

A further solvent mixture which provides a resist composition with storage stability and a good pattern profile is proposed in Patent Document 3 as comprising propylene glycol monoalkyl ether acetate, propylene glycol monoalkyl ether, and ethyl lactate. The solvent mixture becomes effective when a proportion of ethyl lactate is 30 to 90% by weight based on the total solvent weight.

Citation List

Patent Document 1: JP-A 2000-267269

Patent Document 2: JP-A 2001-183837

Patent Document 3: JP-A H07-084359

Patent Document 4: WO 2001/080292

Patent Document 5: US 2007105042 (JP-A 2007-132998)

Patent Document 6: US 2007160929 (JP-A 2007-182488)

Patent Document 7: US 2007190458 (JP-A 2007-212941)

Patent Document 8: US 2006166133 (JP-A 2006-201532)

Patent Document 9: U.S. Pat. No. 6,861,198 (JP-A 2003-233185)

Patent Document 10: JP-A 2006-145775

Patent Document 11: JP 2906999

Patent Document 12: JP-A H09-301948

Patent Document 13: U.S. Pat. No. 6,004,724

Patent Document 14: U.S. Pat. No. 6,261,738

Patent Document 15: JP-A 2000-314956

Patent Document 16: JP-A H09-95479

Patent Document 17: JP-A H09-230588

Patent Document 18: JP-A H09-208554

### SUMMARY OF INVENTION

### Technical Problem

The recent drive for higher integration of integrated circuits trends toward miniaturizing the resist pattern to a feature size of 50 nm or less. An attempt to achieve such a fine feature size, if the thickness of a resist film is kept unchanged from the prior art, results in a resist pattern which has too high an “aspect ratio” (film thickness/feature width) to withstand deformation during development and eventually collapses. For this reason, the miniaturization entails a thickness reduction of the resist film. In an attempt to form a pattern with a feature size of 50 nm or less, for example, the thickness of a resist film must be reduced to 150 nm or less. In the case of multilayer lithography, an attempt was made to form a fine size pattern using a resist film having a thickness of 10 nm to 100 nm, as reported in Patent Document 4.

In an attempt to form a resist pattern with a finer size using a resist film having a reduced thickness, LER becomes a more serious problem as the pattern feature size is reduced. The problem remains unsolved even when well-known improved solvent systems including those of Patent Document 2 are used, particularly in an attempt to form a pattern with a feature size of 50 nm or less.

It is believed that line edge roughness (LER) is caused by enlargement of the size of micro-domains created in a resist film upon coating and heterogeneous reaction due to non-uniform distribution of acid generator and other components in a resist film. The inventors confirmed that lo the domain size is enlarged particularly when the resist film thickness is reduced with a goal to reduce the pattern feature size. The non-uniform distribution of components in a resist film becomes more prominent as the resist film thickness is reduced.

Besides the above-discussed problem, another problem arises with an EB resist material for use in the preparation of photomasks. When photomasks are prepared by spin coating an EB resist material, the rotational speed and other parameters of the spin coating method are limited because photomask blank substrates having a substantial weight are used. If a resist composition based on a conventional solvent system is used, it may not be effectively coated. There arises a problem of severer LER than in the case of pattern formation on semiconductor wafers.

An object of the invention is to provide a chemically amplified resist composition which is applicable to form a resist film having a thickness of up to 150 nm to be processed by photolithography for micropatterning, especially lithography using a light source such as a KrF laser, ArF laser, F₂ laser, extremely short UV, electron beam or x-ray and which has the advantages of improved line edge roughness (LER), high resolution, satisfactory pattern profile and practically acceptable storage stability. Another object of the invention is to provide a patterning process using the resist composition.

### Solution to Problem

The inventors have found that when a certain solvent system is used to formulate a resist composition, this solvent system ensures to form a uniform resist film even when the film is thin enough, i.e., to reduce the domain size on film surface and meets storage stability. In addition, this solvent system enables to form a resist film which possesses a high resolution and improved transfer performance due to a good pattern profile.

Accordingly, in a first aspect (claim 1), the invention provides a chemically amplified resist composition comprising a base resin, an acid generator, and a solvent, wherein a resist film of the composition changes its solubility in a developer under the action of an acid generated by the acid generator upon exposure to high-energy radiation. The composition contains the solvent in a total amount of 1,400 to 5,000 parts, preferably 1,400 to 3,500 parts by weight per 100 parts by weight of the base resin. The solvent comprises propylene glycol monomethyl ether acetate (PGMEA) and ethyl lactate (EL) which are present in a total amount of at least 60% by weight of the total solvent weight. A weight proportion of PGMEA relative to the total solvent weight is higher than a weight proportion of any other solvent relative to the total solvent weight. A weight proportion of EL is 10% to 40% by weight of the total solvent weight. The solvent further comprises at least one third solvent selected from the group consisting of γ-butyrolactone, alkyl acetoacetate, dipropylene glycol methyl ether acetate, dipropylene glycol butyl ether, tripropylene glycol butyl ether, ethylene carbonate, and propylene carbonate, in a proportion of 0.2% to 20% by weight of the total solvent weight. This resist composition ensures that a resist pattern with improved LER is formed from a resist film having a thickness equal to or less than 150 nm. The composition is also satisfactory in resolution and storage stability.

In a preferred embodiment (claim 2), the chemically amplified resist composition comprises as main components, (A-1) a base resin having acid labile group-protected acidic functional groups which is alkali insoluble or substantially alkali insoluble, but becomes alkali soluble when the acid labile groups are eliminated,

(B) the acid generator, and

(C) a nitrogen-containing compound serving as a base, the composition being positive working.

In another preferred embodiment (claim 3), the chemically amplified resist composition comprises as main components,

(A-2) a base resin which is alkali soluble, but becomes alkali insoluble in the presence of an acid catalyst and/or a combination of a crosslinker and a base resin which is alkali soluble, but becomes alkali insoluble through reaction with the crosslinker in the presence of an acid catalyst,

(B) the acid generator, and

(C) a nitrogen-containing compound serving as a base, the composition being negative working.

In a second aspect (claim 4), the invention provides a process for forming a resist pattern, comprising the steps of forming a resist film on a processable substrate, the film forming step including coating the above-described resist composition onto the substrate and prebaking the coating to remove any excess solvent therein, exposing patternwise the resist film to high-energy radiation, optionally post-exposure baking, and developing the exposed resist film with a developer to form a resist pattern. The use of the above-described resist composition ensures to form a resist film which is free of coarse domains having a diameter of at least 50 angstroms. This, in turn, ensures to form a resist pattern with minimized LER. As used herein, the term “processable substrate” refers to a substrate to be processed.

In preferred embodiments (claims 5 and 6), the resist film resulting from the film forming step has a thickness of 10 nm to 150 nm, and more preferably 10 nm to 100 nm. The patterning process of the invention solves the problem that larger size domains are likely to form when a resist film formed is thin, i.e., has a thickness equal to or less than 150 nm, especially equal to or less than 100 nm. Then a satisfactory resist pattern with minimized LER is available.

In a preferred embodiment (claim 7), the resist pattern resulting from patternwise exposure and development has a minimum line width equal to or less than 50 nm. When a pattern having a minimum line width of 50 nm is to be formed, the thickness of a resist film must be reduced below the conventional thickness, affording a likelihood for larger size domains to form so that LER has a more detrimental impact on the resist pattern, giving rise to a problem of significance. The embodiment overcomes this problem.

In a further preferred embodiment (claim 8) of the resist pattern forming process, the processable substrate is a photomask blank. When the resist composition is coated onto a processable substrate in the form of a photomask blank to form a resist film thereon, the coating method is limited because the processable substrate is not a disc which is advantageously rotatable, and larger size domains are thus likely to form. This problem is solved by the pattern forming process of the invention.

### Advantageous Effects of Invention

The resist composition of the invention which is formulated using a solvent mixture containing specific amounts of PGMEA, EL and at least one third solvent selected from the group consisting of γ-butyrolactone, alkyl acetoacetate, dipropylene glycol methyl ether acetate, dipropylene glycol butyl ether, tripropylene glycol butyl ether, ethylene carbonate, and propylene carbonate has the advantages including uniformity of a resist film formed therefrom, improved LER after development, and storage stability. The pattern forming process using this resist composition can form a resist pattern having a satisfactory profile.

### DESCRIPTION OF EMBODIMENTS

A process of forming a fine size resist pattern, especially in the preparation of a mask blank having a pattern rule equal to or less than 50 nm involves the steps of resist film formation, electron beam exposure, optional heat treatment and development with a developer. Since a prior art resist composition is difficult to form a fully uniform resist film, the resultant pattern may have an increased LER, indicating that even if the pattern itself can be resolved, the result is substantially meaningless.

In search for a resist composition which can be coated as a uniform resist film and can form a pattern of a satisfactory profile at a high resolution, the inventors have found that a solvent mixture of at least three specific solvents selected from numerous solvents ensures that a thin resist film having a minimized domain size and reduced LER is formed from a resist composition prepared using this solvent mixture. The present invention is predicated on this finding. The resist composition of the invention overcomes the above-discussed problems and achieves significant improvements in resolution and subsequent transfer performance.

Several embodiments of the invention are described below by way of illustration while the invention is not limited thereto.

In our experiment to evaluate a resist composition for use in a photomask manufacturing process, a resist composition was prepared using a 1/1 solvent mixture of propylene glycol monomethyl ether acetate (PGMEA, one of commonly used solvents) and propylene glycol monomethyl ether (PGME) as described in Patent Document 1. The resist composition was applied onto a photomask blank to form a resist film. Since the experiment intended to achieve a finer pattern size, the thickness of a resist film was reduced below the commonly used level. Specifically the resist composition was coated onto a blank substrate to a thickness of 150 nm. Increased variations of in-plane film thickness were observed although such an increase was not found in an ordinary attempt to form a resist film of 300 nm thick. Specifically, the in-plane film thickness range (i.e., the difference between minimum and maximum of film thickness) was more than 8.0 nm relative to the target of 5.0 nm or less. After patternwise writing of this thin resist film with electron beam, the in-plane variation of pattern feature size was increased as well. The pattern had an accordingly increased value of LER, which was also a problem.

In another experiment wherein a resist composition was prepared using a 1/1 solvent mixture of propylene glycol monomethyl ether acetate (PGMEA) and ethyl lactate (EL) as described in Patent Document 2, the in-plane film thickness range was within the target value. A pattern with a fine size of 50 nm could be formed. This pattern had an acceptable value of LER.

To find the cause accounting for the difference between these experiments, the surface state of the coated films was observed under an atomic force microscope (AFM) for comparison. For the PGMEA/EL solvent mixture, a smaller domain size on the resist surface was confirmed. From this result, a possibility was deduced that the difference in evaporation rate between solvents has an impact on the uniform distribution of components in a resist film.

It is believed that the reason why a problem of LER arises as the film thickness is further reduced can be similarly illuminated. Then resist films having a thickness of 160 nm and 80 nm were formed, and their surface state was observed under AFM for comparison. It was found that the domain size increases as the film thickness becomes thinner. It is presumed that this domain size increase is the cause of compromising LER.

The inventors presumed that the cause for the above-discussed problems is as follows. To form a resist film of up to 150 nm by spin coating, the concentration of resist components must be reduced (by increasing the amount of solvent) as compared with the conventional composition. Particularly in the case of photomask blanks, it is difficult to increase the rotational speed of spin coating beyond 3,000 rpm due to limitations associated with the shape, weight and other factors of substrates, which necessitates to use a dilute composition. Such a resist composition diluted to a low concentration has a possibility that owing to solvent evaporation continuing from the coating step to the prebaking step, a non-uniform distribution of components within a film manifests more distinctly at the same time as a variation of film thickness. It is believed that this non-uniform distribution of components causes to increase LER. More specifically, it is believed that what accounts for the empirical result that the in-plane film thickness variation was suppressed to 3.0 nm or less when a resist composition using a 1/1 solvent mixture of PGMEA and EL was coated onto a photomask blank substrate to a thickness of 150 nm, but the variation increased to about 8.0 nm when EL was replaced by PGME is the boiling point of these solvents. It is presumed that EL due to its high boiling point (154° C.) has a slower evaporation rate than PGME (121° C.) so that EL is effective in suppressing the in-plane variation of film thickness.

On the other hand, ethyl lactate (EL) is notorious for its negative impact on the storage stability of a resist composition. For example, a chemically amplified resist composition containing at least 50% by weight of EL based on the total solvent weight is allowed to stand in an air-unshielded atmosphere at room temperature for one month, there arises a practical problem that it is difficult to suppress a change of its sensitivity within the acceptable range of 5%. It is then believed essential for the desired storage stability that the proportion of EL be reduced to or below 40% by weight based on the total solvent weight. Then replacement of a part of EL by PGME is thought to offer the simplest means for solving the above-discussed problem and the storage stability problem. In an actual trial, however, the partial replacement of EL by PGME entailed a decline of performance. In particular, an apparent increase of LER was observed when the film thickness was reduced to or below 100 nm as one of severer conditions.

The above consideration suggests that the control of solvent boiling point is crucial to solve the problems of lo film thickness variations and LER increases encountered during formation of a film having a thickness of up to 150 nm. However, it is known that a pattern of an acceptable profile is not achievable when high boiling solvents such as diethylene glycol solvents are used as the major solvent.

Then, among solvent systems of PGMEA combined with EL, the inventors selected a solvent mixture in which a proportion of EL is reduced to or below 40% by weight based on the total solvent weight for the purpose of storage stability, and a high-boiling solvent is added. This combination has been found to succeed in minimizing the in-plane variation of film thickness. It has also been found that a resist pattern resulting from a resist composition using this solvent system is also improved in LER. Although the pattern is likely to have increased LER at a reduced film thickness of 100 nm or less as previously described, the addition of a high boiling solvent is effective for improving LER even at such reduced thickness.

The solvent mixture as used herein is described in further detail.

The solvent (mixture) that constitutes the resist composition of the invention contains propylene glycol monomethyl ether acetate (PGMEA) and ethyl lactate (EL) and further contains at least one third solvent selected from the group consisting of γ-butyrolactone, alkyl acetoacetate (wherein the alkyl group is preferably a straight or branched alkyl group having 1 to 4 carbon atoms), dipropylene glycol methyl ether acetate, dipropylene glycol butyl ether, tripropylene glycol butyl ether, ethylene carbonate, and propylene carbonate.

The third solvent which is added to the PGMEA/EL system is selected from the group consisting of γ-butyrolactone, alkyl acetoacetate, dipropylene glycol methyl ether acetate, dipropylene glycol butyl ether, tripropylene glycol butyl ether, ethylene carbonate, and propylene carbonate, and combinations thereof. Among others, those solvents having a boiling point of at least 200° C., i.e., γ-butyrolactone, dipropylene glycol methyl ether acetate, tripropylene glycol butyl ether, dipropylene glycol butyl ether, ethylene carbonate, and propylene carbonate are more effective in forming a uniform coating film and improving LER, with dipropylene glycol butyl ether, tripropylene glycol butyl ether, and dipropylene glycol methyl ether acetate being even more preferred.

The proportions of the foregoing solvents must be individually adjusted in accordance with a choice of resist components other than the solvents, the desired thickness of a resist film, and the like. To insure the desired storage stability, it is preferred that a proportion of PGMEA in the mixture be the highest among the solvents.

To insure a solubility of other components, typically acid generator, in the solvent mixture and hence, a uniform distribution thereof in a film and to provide a spin coating amenability, a proportion of EL should be in the range from 10% to 40% by weight based on the total solvent weight. Less than 10 wt % of EL gives rise to problems with respect to acid generator solubility and coating property. Even at an EL proportion of less than 10 wt %, a uniform film can sometimes be formed by a careful choice of coating parameters, but a complex recipe is necessary therefor. With EL in excess of 40 wt %, it is difficult to meet the requirement of storage stability.

The proportion of at least one third (high-boiling) solvent selected from the group consisting of γ-butyrolactone, alkyl acetoacetate, dipropylene glycol methyl ether acetate, dipropylene glycol butyl ether, tripropylene glycol butyl ether, ethylene carbonate, and propylene carbonate is set in the range from 0.2% to 20% by weight based on the total solvent weight. Better results are obtained at a proportion of 0.2% to 10% by weight, and especially 1.0% to 10% by weight. Less than 0.2 wt % of the third solvent is less effective for facilitating coating whereas more than 20 wt % of the third solvent has a tendency that a resist pattern is undesirably constricted in cross-sectional shape.

In the resist composition, any well-known resist solvents (referred to as “fourth solvent”) may be added to the mixture of the foregoing three solvents as long as this does not compromise the effects by a unique combination of three solvents, that is, as long as [1] the total amount of PGMEA and EL is at least 60% by weight of the total solvent weight, [2] a weight proportion of PGMEA relative to the total solvent weight is the highest among the solvents, [3] a weight proportion of EL is in the preferred range (10-40 wt %), and [4] a proportion of the third solvent is in the preferred range (0.2-20 wt %). Examples of the well-known solvents which can be added herein include ketones such as cyclohexanone and methyl-2-n-amylketone; alcohols such as 3-methoxybutanol, 3-methyl-3-methoxybutanol, 1-methoxy-2-propanol and 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; and esters such as propylene glycol monoethyl ether acetate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate.

Of the fourth solvents, if added, propylene glycol monomethyl ether (PGME) is typical. In an embodiment wherein acid generators such as onium salts are contained in a relatively high concentration in order to enhance the resist sensitivity, PGME may be added for the purpose of improving the solubility of these components. The addition of PGME is effective when the onium salt is added in an amount of at least 7% by weight relative to the base polymer, for example, although the effectiveness varies, of course, depending on the structure of onium salt. PGME's effect of increasing the solubility of acid generator or the like is expectable when PGME is added in an amount of at least 10% by weight. Since PGME undesirably has a negative impact on coating property, it is preferred in addition to the above-limited ranges of the three solvents that the amount of PGME added be up to 40% by weight. This range of PGME added has no negative impact on storage stability and allows an acid generator to be added in a relatively large amount so that a resist pattern having a high sensitivity and minimized LER may be obtained.

As used herein, the solvent mixture containing PGMEA and EL and further containing at least one third solvent selected from the group consisting of γ-butyrolactone, alkyl acetoacetate, dipropylene glycol methyl ether acetate, dipropylene glycol butyl ether, tripropylene glycol butyl ether, ethylene carbonate, and propylene carbonate has the advantage that a base resin, acid generator and additives can be homogeneously dissolved therein to form a resist composition, so that a resist film having a uniform distribution of components therein may be formed therefrom. When this resist film is worked through a series of steps from exposure to development, the resulting resist pattern is improved in LER. In addition, the resist composition has satisfactory storage stability.

The amount of the solvent mixture used in preparation of a resist composition should be determined appropriate, depending on the desired thickness of a resist film. When it is desired to form a satisfactory coating film having a thickness of 10 to 150 nm, the solvent mixture is preferably used in an amount of 1,400 to 5,000 parts, and more preferably 2,000 to 3,600 parts by weight per 100 parts by weight of the base resin.

While the solvent mixture is used to dissolve resist components therein to form a chemically amplified resist composition so that the resist composition may be effectively coated onto a processable substrate as mentioned above, the resist composition may be either positive or negative working.

In addition to the solvent mixture, the chemically amplified positive resist composition typically comprises:

(A-1) a base resin having acid labile group-protected acidic functional groups which is alkali insoluble or substantially alkali insoluble, but becomes alkali soluble when the acid labile groups are eliminated,

(B) an acid generator, and

(C) a nitrogen-containing compound serving as a base.

The base polymers used as component (A-1) in the chemically amplified positive resist compositions include polyhydroxystyrene (PHS), and copolymers of hydroxystyrene with styrene, (meth)acrylic acid esters or other polymerizable olefinic compounds, for KrF excimer laser and EB resist uses (see Patent Document 5, for example); (meth)acrylic acid ester polymers, alternating copolymers of cycloolefin with maleic anhydride, similar alternating copolymers further containing vinyl ethers or (meth)acrylic acid esters, polynorbornene, and ring-opening metathesis polymerized cycloolefins, for ArF excimer laser resist use (see Patent Document 6, for example); and fluorinated forms of the foregoing polymers (for both KrF and ArF laser uses) and polymers resulting from ring-closure polymerization using fluorinated dienes for F₂ laser resist use. Silicon-substituted forms of the foregoing polymers and polysilsesquioxane polymers are useful for the bilayer resists (see Patent Document 7, for example). The base resin is not limited to these polymer systems. The base polymers may be used alone or in admixture of two or more. In the case of positive resist compositions, it is a common practice to substitute acid labile groups for hydroxyl groups on phenol, carboxyl groups or fluorinated alkyl alcohols for reducing the rate of dissolution in unexposed regions.

The acid labile groups to be introduced into the base polymers may be selected from a variety of such groups, preferably from acetal groups of 2 to 30 carbon atoms and tertiary alkyl groups of 4 to 30 carbon atoms having the formulae (P1) and (P2), respectively.

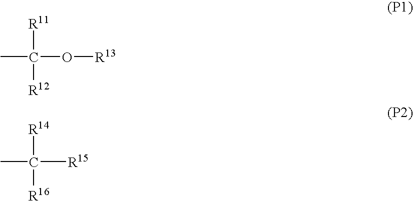

In formulae (P1) and (P2), R¹¹ and R¹² each are hydrogen or a straight, branched or cyclic alkyl group of 1 to 20 carbon atoms, preferably 1 to 12 carbon atoms, which may contain a heteroatom such as oxygen, sulfur, nitrogen or fluorine, R¹³, R¹⁴, R¹⁵ and R¹⁶ each are a straight, branched or cyclic alkyl group, aryl group or aralkyl group of 1 to 20 carbon atoms, preferably 1 to 12 carbon atoms, which may contain a heteroatom such as oxygen, sulfur, nitrogen or fluorine. A pair of R¹¹ and R¹², a pair of R¹¹ and R¹³, a pair of R¹² and R¹³, a pair of R¹⁴ and R¹⁵, a pair of R¹⁴ and R¹⁶, or a pair of R¹⁵ and R¹⁶, taken together, may form a non-aromatic ring of 3 to 20 carbon atoms, preferably 3 to 12 carbon atoms, with the carbon or oxygen atom to which they are attached.

Illustrative examples of the acetal group of formula (P1) include, but are not limited to, methoxymethyl, ethoxymethyl, propoxymethyl, butoxymethyl, isopropoxymethyl, t-butoxymethyl, 1-methoxyethyl, 1-methoxypropyl, 1-methoxybutyl, 1-ethoxyethyl, 1-ethoxypropyl, 1-ethoxybutyl, 1-propoxyethyl, 1-propoxypropyl, 1-propoxybutyl, 1-cyclopentyloxyethyl, 1-cyclohexyloxyethyl, 2-methoxyisopropyl, 2-ethoxyisopropyl, 1-phenoxyethyl, 1-benzyloxyethyl, 1-phenoxypropyl, 1-benzyloxypropyl, 1-adamantyloxyethyl, 1-adamantyloxypropyl, 2-tetrahydrofuryl, 2-tetrahydro-2H-pyranyl, 1-(2-cyclohexanecarbonyloxyethoxy)ethyl, 1-(2-cyclohexanecarbonyloxyethoxy)propyl, 1-[2-(1-adamantylcarbonyloxy)ethoxy]ethyl, and 1-[2-(1-adamantylcarbonyloxy)ethoxy]propyl.

Illustrative examples of the tertiary alkyl group of formula (P2) include, but are not limited to, t-butyl, t-pentyl, 1-ethyl-1-methylpropyl, 1,1-diethylpropyl, 1,1,2-trimethylpropyl, 1-adamantyl-1-methylethyl, 1-methyl-1-(2-norbornyl)ethyl, 1-methyl-1-(tetrahydrofuran-2-yl)ethyl, 1-methyl-1-(7-oxanorbornan-2-yl)ethyl, 1-methylcyclopentyl, 1-ethylcyclopentyl, 1-propylcyclopentyl, 1-cyclopentylcyclopentyl, 1-cyclohexylcyclopentyl, 1-(2-tetrahydrofuryl)cyclopentyl, 1-(7-oxanorbornan-2-yl)cyclopentyl, 1-methylcyclohexyl, 1-ethylcyclohexyl, 1-cyclopentylcyclohexyl, 1-cyclohexylcyclohexyl, 2-methyl-2-norbornyl, 2-ethyl-2-norbornyl, 8-methyl-8-tricyclo[5.2.1.0^{2,6}]decyl, 8-ethyl-8-tricyclo[5.2.1.0^{2,6}]decyl, 3-methyl-3-tetracyclo[4.4.0.1^{2,5}.1^{7,10}]dodecyl, 3-ethyl-3-tetracyclo[4.4.0.1^{2,5}.1^{7,10}]dodecyl, 2-methyl-2-adamantyl, 2-ethyl-2-adamantyl, 1-methyl-3-oxo-1-cyclohexyl, 1-methyl-1-(tetrahydrofuran-2-yl)ethyl, 5-hydroxy-2-methyl-2-adamantyl, and 5-hydroxy-2-ethyl-2-adamantyl.

In the base resin, some hydroxyl groups may be linked via acid labile groups of the following general formula (P3a) or (P3b) for crosslinkage between molecules or within a molecule.

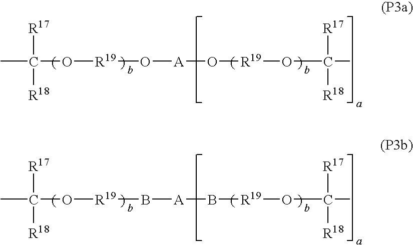

Herein, R¹⁷ and R¹⁸ each are hydrogen or a straight, branched or cyclic alkyl group of 1 to 8 carbon atoms, or R¹⁷ and R¹⁸, taken together, may form a ring with the carbon atom to which they are attached. Each of R¹⁷ and R¹⁸ is a straight or branched alkylene group of 1 to 8 carbon atoms when they form a ring. R¹⁹ is a straight, branched or cyclic alkylene group of 1 to 10 carbon atoms. Letter “a” is an integer of 1 to 7, and “b” is 0 or an integer of 1 to 10. “A” is a (a+1)-valent aliphatic or alicyclic saturated hydrocarbon group, aromatic hydrocarbon group or heterocyclic group of 1 to 50 carbon atoms, which may have an intervening heteroatom and in which some hydrogen atoms may be replaced by hydroxyl groups, carboxyl groups, carbonyl groups or fluorine atoms. B is —CO—O—, —NHCO—O— or —NHCONH—.

Illustrative examples of the crosslinking acetal linkages represented by formulae (P3a) and (P3b) are given below as (P3)-1 through (P3)-8, but not limited thereto.

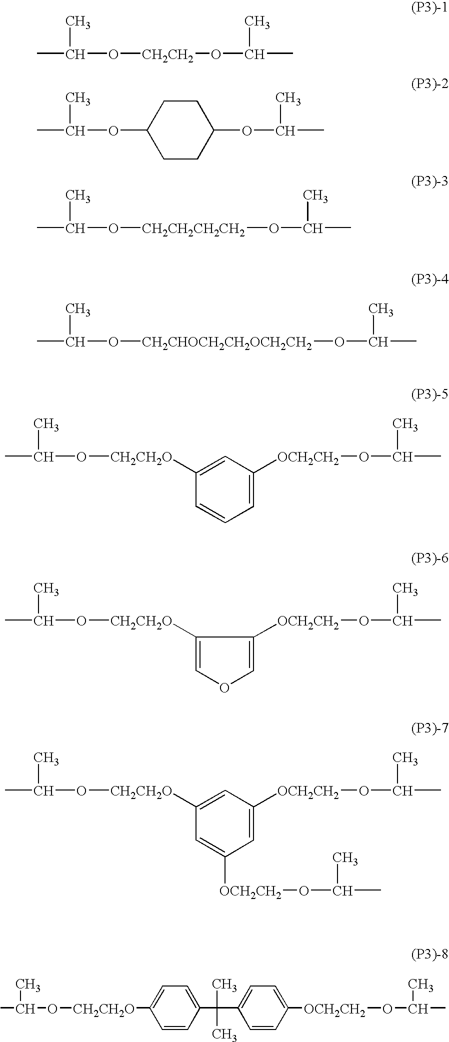

Preferably the base polymer has a weight average molecular weight (Mw) of 2,000 to 100,000 as measured by gel permeation chromatography (GPC) using polystyrene standards. With Mw below 2,000, film formation and resolution may become poor. With Mw beyond 100,000, resolution may become poor or foreign matter may generate during pattern formation.

In addition to the solvent mixture, the chemically amplified negative resist composition typically comprises:

(A-2) a base resin which is alkali soluble, but lo becomes alkali insoluble in the presence of an acid catalyst and/or a combination of a crosslinker and a base resin which is alkali soluble, but becomes alkali insoluble through reaction with the crosslinker in the presence of an acid catalyst,

(B) an acid generator, and

(C) a nitrogen-containing compound serving as a base.

The base polymers used as component (A-2) in the chemically amplified negative resist compositions include polyhydroxystyrene (PHS), and copolymers of hydroxystyrene with styrene, (meth)acrylic acid esters or other polymerizable olefinic compounds, for KrF excimer laser and EB resist uses (see Patent Documents 8 and 9, for example); (meth)acrylic acid ester polymers, alternating copolymers of cycloolefin with maleic anhydride, similar alternating copolymers further containing vinyl ethers or (meth)acrylic acid esters, polynorbornene, and ring-opening metathesis polymerized cycloolefins, for ArF excimer laser resist use (see Patent Document 10, for example); and fluorinated forms of the foregoing polymers (for both KrF and ArF laser uses) and polymers resulting from ring-closure polymerization using fluorinated dienes for F₂ laser resist use.

Silicon-substituted forms of the foregoing polymers and polysilsesquioxane polymers are useful for the bilayer resists. The base resin is not limited to these polymer systems. The base polymers may be used alone or in admixture of two or more. In the case of negative resist compositions, it is a common practice to acquire alkali solubility by utilizing hydroxyl groups on phenol, carboxyl groups or fluorinated alkyl alcohols, and on the other hand, to reduce the rate of dissolution of the polymer by causing the polymer to be intermolecularly crosslinked upon acid generation. The latter is achieved by the method of incorporating into the polymer units having substituent groups capable of forming bonds with other units in an electrophilic manner, for example, epoxy and acetal groups and/or the method of adding a crosslinker separately to the polymer.

While the base polymers for use in KrF excimer laser or EB lithography are described in Patent Document 8, for example, typical examples extracted therefrom are shown below.

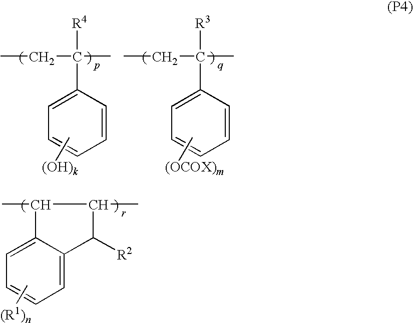

In the above formula, X is a straight or branched alkyl group of 1 to 4 carbon atoms or a straight or branched alkoxy group of 1 to 4 carbon atoms, R¹ and R² are each independently a hydrogen atom, hydroxy group, straight or branched alkyl group, substitutable alkoxy group or halogen atom, R³ and R⁴ each are hydrogen or methyl, n is a positive integer of 1 to 4, m and k each are a positive integer of 1 to 5, p, q and r are positive numbers, the polymer having a weight average molecular weight of 1,000 to 5,000,000, as determined by gel permeation chromatography (GPC) relative to polystyrene standards.

In these examples, alkali solubility is provided by the acidity of phenolic hydroxyl groups. Where it is desired to endow a polymer itself with a crosslinking ability, a glycidyl group is incorporated in X so that the polymer may become crosslink-reactive between molecules in the presence of an acid catalyst. Crosslink-reactive units may be incorporated by copolymerizing an acrylic ester whose ester moiety is endowed with crosslink-reactivity.

In the embodiment comprising an alkali soluble base resin combined with a crosslinker, the base polymer may not be provided with electrophilic reactivity.

The crosslinker used in the negative resist composition may be any of crosslinkers which induce intramolecular and intermolecular crosslinkage to the polymer with the aid of the acid generated by the photoacid generator lo as component (B). Suitable crosslinkers include alkoxymethylglycolurils and alkoxymethylmelamines.

Examples of suitable alkoxymethylglycolurils include tetramethoxymethylglycoluril, 1,3-bismethoxymethyl-4,5-bismethoxyethylene urea, and bismethoxymethyl urea. Examples of suitable alkoxymethylmelamines include hexamethoxymethylmelamine and hexaethoxymethylmelamine.

A crosslinker having no chemical amplifying function may be added in an auxiliary manner. Typical crosslinkers having no chemical amplifying function and providing a high sensitivity are polyfunctional azides. Suitable polyfunctional azides include 4,4′-diazidophenyl sulfide, bis(4-azidobenzyl)methane, bis(3-chloro-4-azidobenzyl)methane, bis-4-azidobenzylidene, 2,6-bis(4-azidobenzylidene)-cyclohexanone, and 2,6-bis(4-azidobenzylidene)-4-methylcyclohexanone.

Typical of the acid generator (B) is a photoacid generator. The photoacid generator may be any of compounds which generate acid upon exposure to high-energy radiation. Suitable photoacid generators include sulfonium salts, iodonium salts, sulfonyldiazomethane and N-sulfonyloxyimide photoacid generators. Exemplary photoacid generators are given below while they may be used alone or in admixture of two or more.

Sulfonium salts are salts of sulfonium cations with sulfonate anions. Exemplary sulfonium cations include triphenylsulfonium, (4-tert-butoxyphenyl)diphenylsulfonium, bis(4-tert-butoxyphenyl)phenylsulfonium, tris(4-tert-butoxyphenyl)sulfonium, (3-tert-butoxyphenyl)diphenylsulfonium, bis(3-tert-butoxyphenyl)phenylsulfonium, tris(3-tert-butoxyphenyl)sulfonium, (3,4-di-tert-butoxyphenyl)diphenylsulfonium, bis(3,4-di-tert-butoxyphenyl)phenylsulfonium, tris(3,4-di-tert-butoxyphenyl)sulfonium, diphenyl(4-thiophenoxyphenyl)sulfonium, (4-tert-butoxycarbonylmethyloxyphenyl)diphenylsulfonium, tris(4-tert-butoxycarbonylmethyloxyphenyl)sulfonium, (4-tert-butoxyphenyl)bis(4-dimethylaminophenyl)sulfonium, tris(4-dimethylaminophenyl)sulfonium, 2-naphthyldiphenylsulfonium, dimethyl-2-naphthylsulfonium, 4-hydroxyphenyldimethylsulfonium, 4-methoxyphenyldimethylsulfonium, trimethylsulfonium, 2-oxocyclohexylcyclohexylmethylsulfonium, trinaphthylsulfonium, tribenzylsulfonium, diphenylmethylsulfonium, dimethylphenylsulfonium, and 2-oxo-2-phenylethylthiacyclopentanium. Exemplary sulfonates include trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, mesitylenesulfonate, 2,4,6-triisopropylbenzenesulfonate, toluenesulfonate, benzenesulfonate, 4-(4-toluenesulfonyloxy)benzenesulfonate, naphthalenesulfonate, camphorsulfonate, octanesulfonate, dodecylbenzenesulfonate, butanesulfonate, and methanesulfonate. Sulfonium salts based on combination of the foregoing examples are included.

Iodinium salts are salts of iodonium cations with sulfonate anions. Exemplary iodonium cations are aryliodonium cations including diphenyliodinium, bis (4-tert-butylphenyl)iodonium, 4-tert-butoxyphenylphenyliodonium, and 4-methoxyphenylphenyliodonium. Exemplary sulfonates include trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, mesitylenesulfonate, 2,4,6-triisopropylbenzenesulfonate, toluenesulfonate, benzenesulfonate, 4-(4-toluenesulfonyloxy)benzenesulfonate, naphthalenesulfonate, camphorsulfonate, octanesulfonate, dodecylbenzenesulfonate, butanesulfonate, and methanesulfonate. Iodonium salts based on combination of the foregoing examples are included.

Exemplary sulfonyldiazomethane compounds include bissulfonyldiazomethane compounds and sulfonyl-carbonyldiazomethane compounds such as bis(ethylsulfonyl)diazomethane, bis(1-methylpropylsulfonyl)diazomethane, bis(2-methylpropylsulfonyl)diazomethane, bis(1,1-dimethylethylsulfonyl)diazomethane, bis(cyclohexylsulfonyl)diazomethane, bis(perfluoroisopropylsulfonyl)diazomethane, bis(phenylsulfonyl)diazomethane, bis(4-methylphenylsulfonyl)diazomethane, bis(2,4-dimethylphenylsulfonyl)diazomethane, bis(2-naphthylsulfonyl)diazomethane, bis(4-acetyloxyphenylsulfonyl)diazomethane, bis(4-methanesulfonyloxyphenylsulfonyl)diazomethane, bis(4-(4-toluenesulfonyloxy)phenylsulfonyl)diazomethane, bis(4-acetyloxyphenylsulfonyl)diazomethane, bis(4-(n-hexyloxy)phenylsulfonyl)diazomethane, bis(2-methyl-4-(n-hexyloxy)phenylsulfonyl)diazomethane, bis(2,5-dimethyl-4-(n-hexyloxy)phenylsulfonyl)diazomethane, bis(3,5-dimethyl-4-(n-hexyloxy)phenylsulfonyl)diazomethane, bis(2-methyl-5-isopropyl-4-(n-hexyloxy)phenylsulfonyl)-diazomethane, 4-methylphenylsulfonylbenzoyldiazomethane, tert-butylcarbonyl-4-methylphenylsulfonyldiazomethane, 2-naphthylsulfonylbenzoyldiazomethane, 4-methylphenylsulfonyl-2-naphthoyldiazomethane, methylsulfonylbenzoyldiazomethane, and tert-butoxycarbonyl-4-methylphenylsulfonyldiazomethane.

N-sulfonyloxyimide photoacid generators include combinations of imide skeletons with sulfonates. Exemplary imide skeletons are succinimide, naphthalene dicarboxylic acid imide, phthalimide, cyclohexyldicarboxylic acid imide, 5-norbornene-2,3-dicarboxylic acid imide, and 7-oxabicyclo[2.2.1]-5-heptene-2,3-dicarboxylic acid imide. Exemplary sulfonates include trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, mesitylenesulfonate, 2,4,6-triisopropylbenzenesulfonate, toluenesulfonate, benzenesulfonate, naphthalenesulfonate, camphorsulfonate, octanesulfonate, dodecylbenzenesulfonate, butanesulfonate, and methanesulfonate.

Additionally, other photoacid generators as listed below are useful. Benzoinsulfonate photoacid generators include benzoin tosylate, benzoin mesylate, and benzoin butanesulfonate.

Pyrogallol trisulfonate photoacid generators include pyrogallol, phloroglucin, catechol, resorcinol, hydroquinone, in which all the hydroxyl groups are substituted with sulfonate groups such as trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, toluenesulfonate, benzenesulfonate, naphthalenesulfonate, camphorsulfonate, octanesulfonate, dodecylbenzenesulfonate, butanesulfonate, and methanesulfonate.

Nitrobenzyl sulfonate photoacid generators include 2,4-dinitrobenzyl sulfonate, 2-nitrobenzyl sulfonate, and 2,6-dinitrobenzyl sulfonate, with exemplary sulfonates including trifluoromethanesulfonate, nonafluorobutanesulfonate, heptadecafluorooctanesulfonate, 2,2,2-trifluoroethanesulfonate, pentafluorobenzenesulfonate, 4-trifluoromethylbenzenesulfonate, 4-fluorobenzenesulfonate, toluenesulfonate, benzenesulfonate, naphthalenesulfonate, camphorsulfonate, octanesulfonate, dodecylbenzenesulfonate, butanesulfonate, and methanesulfonate. Also useful are analogous nitrobenzyl sulfonate compounds in which the nitro group on the benzyl side is substituted by a trifluoromethyl group.

Sulfone photoacid generators include bis(phenylsulfonyl)methane, bis(4-methylphenylsulfonyl)methane, bis(2-naphthylsulfonyl)methane, 2,2-bis(phenylsulfonyl)propane, 2,2-bis(4-methylphenylsulfonyl)propane, 2,2-bis(2-naphthylsulfonyl)propane, 2-methyl-2-(p-toluenesulfonyl)propiophenone, 2-cyclohexylcarbonyl-2-(p-toluenesulfonyl)propane, and 2,4-dimethyl-2-(p-toluenesulfonyl)pentan-3-one.

Glyoxime derivative photoacid generators are described in Patent Documents 11 and 12 and include bis-O-(p-toluenesulfonyl)-α-dimethylglyoxime, bis-O-(p-toluenesulfonyl)-α-diphenylglyoxime, bis-O-(p-toluenesulfonyl)-α-dicyclohexylglyoxime, bis-O-(p-toluenesulfonyl)-2,3-pentanedioneglyoxime, bis-O-(n-butanesulfonyl)-α-dimethylglyoxime, bis-O-(n-butanesulfonyl)-α-diphenylglyoxime, bis-O-(n-butanesulfonyl)-α-dicyclohexylglyoxime, bis-O-(methanesulfonyl)-α-dimethylglyoxime, bis-O-(trifluoromethanesulfonyl)-α-dimethylglyoxime, bis-O-(2,2,2-trifluoroethanesulfonyl)-α-dimethylglyoxime, bis-O-(10-camphorsulfonyl)-α-dimethylglyoxime, bis-O-(benzenesulfonyl)-α-dimethylglyoxime, bis-O-(p-fluorobenzenesulfonyl)-α-dimethylglyoxime, bis-O-(p-trifluoromethylbenzenesulfonyl)-α-dimethylglyoxime, bis-O-(xylenesulfonyl)-α-dimethylglyoxime, bis-O-(trifluoromethanesulfonyl)-nioxime, bis-O-(2,2,2-trifluoroethanesulfonyl)-nioxime, bis-O-(10-camphorsulfonyl)-nioxime, bis-O-(benzenesulfonyl)-nioxime, bis-O-(p-fluorobenzenesulfonyl)-nioxime, bis-O-(p-trifluoromethylbenzenesulfonyl)-nioxime, and bis-O-(xylenesulfonyl)-nioxime.

Also included are the oxime sulfonates described in Patent Document 13, for example, (5-(4-toluenesulfonyl)oxyimino-5H-thiophen-2-ylidene)phenyl-acetonitrile, (5-(10-camphorsulfonyl)oxyimino-5H-thiophen-2-ylidene)phenyl-acetonitrile, (5-n-octanesulfonyloxyimino-5H-thiophen-2-ylidene)phenyl-acetonitrile, (5-(4-toluenesulfonyl)oxyimino-5H-thiophen-2-ylidene)(2-methylphenyl)acetonitrile, (5-(10-camphorsulfonyl)oxyimino-5H-thiophen-2-ylidene)(2-methylphenyl)acetonitrile, (5-n-octanesulfonyloxyimino-5H-thiophen-2-ylidene)(2-methylphenyl)acetonitrile, etc.

Also included are the oxime sulfonates described in Patent Documents 14 and 15, for example, 2,2,2-trifluoro-1-phenyl-ethanone oxime-O-methylsulfonate; 2,2,2-trifluoro-1-phenyl-ethanone oxime-O-(10-camphorylsulfonate); 2,2,2-trifluoro-1-phenyl-ethanone oxime-O-(4-methoxyphenyl-sulfonate); 2,2,2-trifluoro-1-phenyl-ethanone oxime-O-(1-naphthylsulfonate); 2,2,2-trifluoro-1-phenyl-ethanone oxime-O-(2-naphthylsulfonate); 2,2,2-trifluoro-1-phenyl-ethanone oxime-O-(2,4,6-trimethylphenylsulfonate); 2,2,2-trifluoro-1-(4-methylphenyl)-ethanone oxime-O-(10-camphorylsulfonate); 2,2,2-trifluoro-1-(4-methylphenyl)-ethanone oxime-O-(methyl-sulfonate); 2,2,2-trifluoro-1-(2-methylphenyl)-ethanone oxime-O-(10-camphorylsulfonate); 2,2,2-trifluoro-1-(2,4-dimethylphenyl)-ethanone oxime-O-(10-camphorylsulfonate); 2,2,2-trifluoro-1-(2,4-dimethylphenyl)-ethanone oxime-O-(1-naphthylsulfonate); 2,2,2-trifluoro-1-(2,4-dimethylphenyl)-ethanone oxime-O-(2-naphthylsulfonate); 2,2,2-trifluoro-1-(2,4,6-trimethylphenyl)-ethanone oxime-O-(10-camphoryl-sulfonate); 2,2,2-trifluoro-1-(2,4,6-trimethylphenyl)-ethanone oxime-O-(1-naphthylsulfonate); 2,2,2-trifluoro-1-(2,4,6-trimethylphenyl)-ethanone oxime-O-(2-naphthyl-sulfonate); 2,2,2-trifluoro-1-(4-methoxyphenyl)-ethanone oxime-O-methylsulfonate; 2,2,2-trifluoro-1-(4-methyl-thiophenyl)-ethanone oxime-O-methylsulfonate; 2,2,2-trifluoro-1-(3,4-dimethoxyphenyl)-ethanone oxime-O-methylsulfonate; 2,2,3,3,4,4,4-heptafluoro-1-phenyl-butanone oxime-O-(10-camphorylsulfonate); 2,2,2-trifluoro-1-(phenyl)-ethanone oxime-O-methylsulfonate; 2,2,2-trifluoro-1-(phenyl)-ethanone oxime-O-10-camphorylsulfonate; 2,2,2-trifluoro-1-(phenyl)-ethanone oxime-O-(4-methoxyphenyl)sulfonate; 2,2,2-trifluoro-1-(phenyl)-ethanone oxime-O-(1-naphthyl)-sulfonate; 2,2,2-trifluoro-1-(phenyl)-ethanone oxime-O-(2-naphthyl)sulfonate; 2,2,2-trifluoro-1-(phenyl)-ethanone oxime-O-(2,4,6-trimethylphenyl)sulfonate; 2,2,2-trifluoro-1-(4-methylphenyl)-ethanone oxime-O-(10-camphoryl)sulfonate; 2,2,2-trifluoro-1-(4-methylphenyl)-ethanone oxime-O-methyl-sulfonate; 2,2,2-trifluoro-1-(2-methylphenyl)-ethanone oxime-O-(10-camphoryl)sulfonate; 2,2,2-trifluoro-1-(2,4-dimethyl-phenyl)-ethanone oxime-O-(1-naphthyl)sulfonate; 2,2,2-trifluoro-1-(2,4-dimethylphenyl)-ethanone oxime-O-(2-naphthyl)sulfonate; 2,2,2-trifluoro-1-(2,4,6-trimethyl-phenyl)-ethanone oxime-O-(10-camphoryl)sulfonate; 2,2,2-trifluoro-1-(2,4,6-trimethylphenyl)-ethanone oxime-O-(1-naphthyl)sulfonate; 2,2,2-trifluoro-1-(2,4,6-trimethyl-phenyl)-ethanone oxime-O-(2-naphthyl)sulfonate; 2,2,2-trifluoro-1-(4-methoxyphenyl)-ethanone oxime-O-methyl-sulfonate; 2,2,2-trifluoro-1-(4-thiomethylphenyl)-ethanone oxime-O-methylsulfonate; 2,2,2-trifluoro-1-(3,4-dimethoxy-phenyl)-ethanone oxime-O-methylsulfonate; 2,2,2-trifluoro-1-(4-methoxyphenyl)-ethanone oxime-O-(4-methylphenyl)sulfonate; 2,2,2-trifluoro-1-(4-methoxyphenyl)-ethanone oxime-O-(4-methoxyphenyl)sulfonate; 2,2,2-trifluoro-1-(4-methoxyphenyl)-ethanone oxime-O-(4-dodecylphenyl)sulfonate; 2,2,2-trifluoro-1-(4-methoxyphenyl)-ethanone oxime-O-octylsulfonate; 2,2,2-trifluoro-1-(4-thiomethylphenyl)-ethanone oxime-O-(4-methoxyphenyl)sulfonate; 2,2,2-trifluoro-1-(4-thiomethyl-phenyl)-ethanone oxime-O-(4-dodecylphenyl)sulfonate; 2,2,2-trifluoro-1-(4-thiomethylphenyl)-ethanone oxime-O-octylsulfonate; 2,2,2-trifluoro-1-(4-thiomethylphenyl)-ethanone oxime-O-(2-naphthyl)sulfonate; 2,2,2-trifluoro-1-(2-methylphenyl)-ethanone oxime-O-methylsulfonate; 2,2,2-trifluoro-1-(4-methylphenyl)ethanone oxime-O-phenyl-sulfonate; 2,2,2-trifluoro-1-(4-chlorophenyl)-ethanone oxime-O-phenylsulfonate; 2,2,3,3,4,4,4-heptafluoro-1-(phenyl)-butanone oxime-O-(10-camphoryl)sulfonate; 2,2,2-trifluoro-1-naphthyl-ethanone oxime-O-methylsulfonate; 2,2,2-trifluoro-2-naphthyl-ethanone oxime-O-methylsulfonate; 2,2,2-trifluoro-1-[4-benzylphenyl]-ethanone oxime-O-methylsulfonate; 2,2,2-trifluoro-1-[4-(phenyl-1,4-dioxa-but-1-yl)phenyl]-ethanone oxime-O-methylsulfonate; 2,2,2-trifluoro-1-naphthyl-ethanone oxime-O-propylsulfonate; 2,2,2-trifluoro-2-naphthyl-ethanone oxime-O-propylsulfonate; 2,2,2-trifluoro-1-[4-benzylphenyl]-ethanone oxime-O-propylsulfonate; 2,2,2-trifluoro-1-[4-methylsulfonylphenyl]-ethanone oxime-O-propylsulfonate; 1,3-bis[1-(4-phenoxyphenyl)-2,2,2-trifluoro-ethanone oxime-O-sulfonyl]phenyl; 2,2,2-trifluoro-1-[4-methylsulfonyloxyphenyl]-ethanone oxime-O-propylsulfonate; 2,2,2-trifluoro-1-[4-methylcarbonyloxyphenyl]-ethanone oxime-O-propylsulfonate; 2,2,2-trifluoro-1-[6H,7H-5,8-dioxonaphth-2-yl]-ethanone oxime-O-propylsulfonate; 2,2,2-trifluoro-1-[4-methoxycarbonylmethoxyphenyl]-ethanone oxime-O-propylsulfonate; 2,2,2-trifluoro-1-[4-(methoxy-carbonyl)-(4-amino-1-oxa-pent-1-yl)-phenyl]-ethanone oxime-O-propylsulfonate; 2,2,2-trifluoro-1-[3,5-dimethyl-4-ethoxyphenyl]-ethanone oxime-O-propylsulfonate; 2,2,2-trifluoro-1-[4-benzyloxyphenyl]-ethanone oxime-O-propylsulfonate; 2,2,2-trifluoro-1-[2-thiophenyl]-ethanone oxime-O-propylsulfonate; and 2,2,2-trifluoro-1-[1-dioxa-thiophen-2-yl)]-ethanone oxime-O-propylsulfonate.

Also included are the oxime sulfonates described in Patent Documents 16 and 17 and the references cited therein, for example,
α-(p-toluenesulfonyloxyimino)-phenylacetonitrile,
α-(p-chlorobenzenesulfonyloxyimino)-phenylacetonitrile,
α-(4-nitrobenzenesulfonyloxyimino)-phenylacetonitrile,
α-(4-nitro-2-trifluoromethylbenzenesulfonyloxyimino)-phenylacetonitrile,
α-(benzenesulfonyloxyimino)-4-chlorophenylacetonitrile,
α-(benzenesulfonyloxyimino)-2,4-dichlorophenylacetonitrile,
α-(benzenesulfonyloxyimino)-2,6-dichlorophenylacetonitrile,
α-(benzenesulfonyloxyimino)-4-methoxyphenylacetonitrile,
α-(2-chlorobenzenesulfonyloxyimino)-4-methoxyphenylaceto-nitrile,
α-(benzenesulfonyloxyimino)-2-thienylacetonitrile,
α-(4-dodecylbenzenesulfonyloxyimino)-phenylacetonitrile,
α-[(4-toluenesulfonyloxyimino)-4-methoxyphenyl]acetonitrile,
α-[(dodecylbenzenesulfonyloxyimino)-4-methoxyphenyl]aceto-nitrile,
α-(tosyloxyimino)-3-thienylacetonitrile,
α-(methylsulfonyloxyimino)-1-cyclopentenylacetonitrile,
α-(ethylsulfonyloxyimino)-1-cyclopentenylacetonitrile,
α-(isopropylsulfonyloxyimino)-1-cyclopentenylacetonitrile,
α-(n-butylsulfonyloxyimino)-1-cyclopentenylacetonitrile,
α-(ethylsulfonyloxyimino)-1-cyclohexenylacetonitrile,
α-(isopropylsulfonyloxyimino)-1-cyclohexenylacetonitrile, and
α-(n-butylsulfonyloxyimino)-1-cyclohexenylacetonitrile.

Suitable bisoxime sulfonates include those described in Patent Document 18, for example,
bis(α-(4-toluenesulfonyloxy)imino)-p-phenylenediacetonitrile,
bis(α-(benzenesulfonyloxy)imino)-p-phenylenediacetonitrile,
bis(α-(methanesulfonyloxy)imino)-p-phenylenediacetonitrile,
bis(α-(butanesulfonyloxy)imino)-p-phenylenediacetonitrile,
bis(α-(10-camphorsulfonyloxy)imino)-p-phenylenediaceto-nitrile,
bis(α-(4-toluenesulfonyloxy)imino)-p-phenylenediacetonitrile,
bis(α-(trifluoromethanesulfonyloxy)imino)-p-phenylenediaceto-nitrile,
bis(α-(4-methoxybenzenesulfonyloxy)imino)-p-phenylenediaceto-nitrile,
bis(α-(4-toluenesulfonyloxy)imino)-m-phenylenediacetonitrile,
bis(α-(benzenesulfonyloxy)imino)-m-phenylenediacetonitrile,
bis(α-(methanesulfonyloxy)imino)-m-phenylenediacetonitrile,
bis(α-(butanesulfonyloxy)imino)-m-phenylenediacetonitrile,
bis(α-(10-camphorsulfonyloxy)imino)-m-phenylenediacetonitrile,
bis(α-(4-toluenesulfonyloxy)imino)-m-phenylenediacetonitrile,
bis(α-(trifluoromethanesulfonyloxy)imino)-m-phenylenediaceto-nitrile,
bis(α-(4-methoxybenzenesulfonyloxy)imino)-m-phenylenediaceto-nitrile, etc.

Of these, preferred photoacid generators are sulfonium salts, bissulfonyldiazomethanes, N-sulfonyloxyimides, and glyoxime derivatives. More preferred photoacid generators are sulfonium salts, bissulfonyldiazomethanes, and N-sulfonyloxyimides. Typical examples include
triphenylsulfonium p-toluenesulfonate,
triphenylsulfonium camphorsulfonate,
triphenylsulfonium pentafluorobenzenesulfonate,
triphenylsulfonium nonafluorobutanesulfonate,
triphenylsulfonium 4-(4′-toluenesulfonyloxy)benzenesulfonate,
triphenylsulfonium 2,4,6-triisopropylbenzenesulfonate,
4-tert-butoxyphenyldiphenylsulfonium p-toluenesulfonate,
4-tert-butoxyphenyldiphenylsulfonium camphorsulfonate,
4-tert-butoxyphenyldiphenylsulfonium 4-(4′-toluenesulfonyl-oxy)benzenesulfonate,
tris(4-methylphenyl)sulfonium camphorsulfonate,
tris(4-tert-butylphenyl)sulfonium camphorsulfonate,
bis(tert-butylsulfonyl)diazomethane,
bis(cyclohexylsulfonyl)diazomethane,
bis(2,4-dimethylphenylsulfonyl)diazomethane,
bis(4-(n-hexyloxy)phenylsulfonyl)diazomethane,
bis(2-methyl-4-(n-hexyloxy)phenylsulfonyl)diazomethane,
bis(2,5-dimethyl-4-(n-hexyloxy)phenylsulfonyl)diazomethane,
bis(3,5-dimethyl-4-(n-hexyloxy)phenylsulfonyl)diazomethane,
bis(2-methyl-5-isopropyl-4-(n-hexyloxy)phenylsulfonyl)-diazomethane,
bis(4-tert-butylphenylsulfonyl)diazomethane,
N-camphorsulfonyloxy-5-norbornene-2,3-dicarboxylic acid imide, and
N-p-toluenesulfonyloxy-5-norbornene-2,3-dicarboxylic acid imide.

In the chemically amplified resist composition, an appropriate amount of the photoacid generator is, but not limited to, 0.1 to 10 parts, and especially 0.1 to 5 parts by weight per 100 parts by weight of the base resin. Too high a proportion of the photoacid generator may give rise to problems of degraded resolution and foreign matter upon development and resist film peeling. The photoacid generators may be used alone or in admixture of two or more. The transmittance of the resist film can be controlled by using a photoacid generator having a low transmittance at the exposure wavelength and adjusting the amount of the photoacid generator added.

In the chemically amplified resist composition, nitrogen-containing compounds may be added as a basic component (C). The basic compound used herein is preferably a compound capable of suppressing the rate of diffusion when the acid generated by the photoacid generator diffuses within the resist film. As is well known in the art, the inclusion of nitrogen-containing compounds holds down the influence of air-borne basic compounds and is thus effective for PED. In addition, they are known to control the influence of substrates.

The nitrogen-containing compound may be any of well-known nitrogen-containing organic compounds used in prior art resist compositions, especially chemically amplified resist compositions. Examples include primary, secondary, and tertiary aliphatic amines, mixed amines, aromatic amines, heterocyclic amines, nitrogen-containing compounds having carboxyl group, nitrogen-containing compounds having sulfonyl group, nitrogen-containing compounds having hydroxyl group, nitrogen-containing compounds having hydroxyphenyl group, alcoholic nitrogen-containing compounds, amide derivatives, imide derivatives, and carbamate derivatives.

Examples of suitable primary aliphatic amines include ammonia, methylamine, ethylamine, n-propylamine, isopropylamine, n-butylamine, isobutylamine, sec-butylamine, tert-butylamine, pentylamine, tert-amylamine, cyclopentylamine, hexylamine, cyclohexylamine, heptylamine, octylamine, nonylamine, decylamine, dodecylamine, cetylamine, methylenediamine, ethylenediamine, and tetraethylenepentamine. Examples of suitable secondary aliphatic amines include dimethylamine, diethylamine, di-n-propylamine, diisopropylamine, di-n-butylamine, diisobutylamine, di-sec-butylamine, dipentylamine, dicyclopentylamine, dihexylamine, dicyclohexylamine, diheptylamine, dioctylamine, dinonylamine, didecylamine, didodecylamine, dicetylamine, N, N-dimethylmethylenediamine, N,N-dimethylethylenediamine, and N,N-dimethyltetraethylenepentamine. Examples of suitable tertiary aliphatic amines include trimethylamine, triethylamine, tri-n-propylamine, triisopropylamine, tri-n-butylamine, triisobutylamine, tri-sec-butylamine, tripentylamine, tricyclopentylamine, trihexylamine, tricyclohexylamine, triheptylamine, trioctylamine, trinonylamine, tridecylamine, tridodecylamine, tricetylamine, N,N,N′,N′-tetramethylmethylenediamine, N,N,N′,N′-tetramethylethylenediamine, and N,N,N′,N′-tetramethyltetraethylenepentamine.

Examples of suitable mixed amines include dimethylethylamine, methylethylpropylamine, benzylamine, phenethylamine, and benzyldimethylamine. Examples of suitable aromatic and heterocyclic amines include aniline derivatives (e.g., aniline, N-methylaniline, N-ethylaniline, N-propylaniline, N,N-dimethylaniline, 2-methylaniline, 3-methylaniline, 4-methylaniline, ethylaniline, propylaniline, trimethylaniline, 2-nitroaniline, 3-nitroaniline, 4-nitroaniline, 2,4-dinitroaniline, 2,6-dinitroaniline, 3,5-dinitroaniline, and N,N-dimethyltoluidine), diphenyl(p-tolyl)amine, methyldiphenylamine, triphenylamine, phenylenediamine, naphthylamine, diaminonaphthalene, pyrrole derivatives (e.g., pyrrole, 2H-pyrrole, 1-methylpyrrole, 2,4-dimethylpyrrole, 2,5-dimethylpyrrole, and N-methylpyrrole), oxazole derivatives (e.g., oxazole and isooxazole), thiazole derivatives (e.g., thiazole and isothiazole), imidazole derivatives (e.g., imidazole, 4-methylimidazole, and 4-methyl-2-phenylimidazole), pyrazole derivatives, furazan derivatives, pyrroline derivatives (e.g., pyrroline and 2-methyl-1-pyrroline), pyrrolidine derivatives (e.g., pyrrolidine, N-methylpyrrolidine, pyrrolidinone, and N-methylpyrrolidone), imidazoline derivatives, imidazolidine derivatives, pyridine derivatives (e.g., pyridine, methylpyridine, ethylpyridine, propylpyridine, butylpyridine, 4-(1-butylpentyl)pyridine, dimethylpyridine, trimethylpyridine, triethylpyridine, phenylpyridine, 3-methyl-2-phenylpyridine, 4-tert-butylpyridine, diphenylpyridine, benzylpyridine, methoxypyridine, butoxypyridine, dimethoxypyridine, 4-pyrrolidinopyridine, 2-(1-ethylpropyl)pyridine, aminopyridine, and dimethylaminopyridine), pyridazine derivatives, pyrimidine derivatives, pyrazine derivatives, pyrazoline derivatives, pyrazolidine derivatives, piperidine derivatives, piperazine derivatives, morpholine derivatives, indole derivatives, isoindole derivatives, 1H-indazole derivatives, indoline derivatives, quinoline derivatives (e.g., quinoline and 3-quinolinecarbonitrile), isoquinoline derivatives, cinnoline derivatives, quinazoline derivatives, quinoxaline derivatives, phthalazine derivatives, purine derivatives, pteridine derivatives, carbazole derivatives, phenanthridine derivatives, acridine derivatives, phenazine derivatives, 1,10-phenanthroline derivatives, adenine derivatives, adenosine derivatives, guanine derivatives, guanosine derivatives, uracil derivatives, and uridine derivatives.

Examples of suitable nitrogen-containing compounds having carboxyl group include aminobenzoic acid, indolecarboxylic acid, and amino acid derivatives (e.g. nicotinic acid, alanine, alginine, aspartic acid, glutamic acid, glycine, histidine, isoleucine, glycylleucine, leucine, methionine, phenylalanine, threonine, lysine, 3-aminopyrazine-2-carboxylic acid, and methoxyalanine). Examples of suitable nitrogen-containing compounds having sulfonyl group include 3-pyridinesulfonic acid and pyridinium p-toluenesulfonate. Examples of suitable nitrogen-containing compounds having hydroxyl group, nitrogen-containing compounds having hydroxyphenyl group, and alcoholic nitrogen-containing compounds include 2-hydroxypyridine, aminocresol, 2,4-quinolinediol, 3-indolemethanol hydrate, monoethanolamine, diethanolamine, triethanolamine, N-ethyldiethanolamine, N,N-diethylethanolamine, triisopropanolamine, 2,2′-iminodiethanol, 2-aminoethanol, 3-amino-1-propanol, 4-amino-1-butanol, 4-(2-hydroxyethyl)morpholine, 2-(2-hydroxyethyl)pyridine, 1-(2-hydroxyethyl)piperazine, 1-[2-(2-hydroxyethoxy)ethyl]piperazine, piperidine ethanol, 1-(2-hydroxyethyl)pyrrolidine, 1-(2-hydroxyethyl)-2-pyrrolidinone, 3-piperidino-1,2-propanediol, 3-pyrrolidino-1,2-propanediol, 8-hydroxyjulolidine, 3-quinuclidinol, 3-tropanol, 1-methyl-2-pyrrolidine ethanol, 1-aziridine ethanol, N-(2-hydroxyethyl)phthalimide, and N-(2-hydroxyethyl)isonicotinamide. Examples of suitable amide derivatives include formamide, N-methylformamide, N,N-dimethylformamide, acetamide, N-methylacetamide, N,N-dimethylacetamide, propionamide, benzamide, and 1-cyclohexylpyrrolidone. Suitable imide derivatives include phthalimide, succinimide, and maleimide. Suitable carbamate derivatives include N-t-butoxycarbonyl-N,N-dicyclohexylamine, N-t-butoxycarbonylbenzimidazole and oxazolidinone.

In addition, organic nitrogen-containing compounds of the following general formula (B)-1 may also be included alone or in admixture.

N(X)ₙ(Y)₃₋ₙ (B)-1

In the formula, n is equal to 1, 2 or 3; side chain Y is independently hydrogen or a straight, branched or cyclic C₁-C₂₀ alkyl group which may contain an ether or hydroxyl group; and side chain X is independently selected from groups of the following general formulas (X)-1 to (X)-3, and two or three X's may bond together to form a ring.

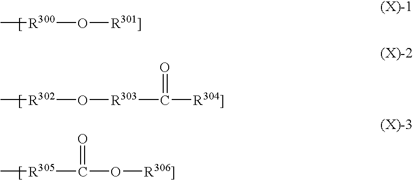

In the formulas, R³⁰⁰, R³⁰² and R³⁰⁵ are independently straight or branched C₁-C₄ alkylene groups; R³⁰¹ and R³⁰⁴ are independently hydrogen, straight, branched or cyclic C₁-C₂₀ alkyl groups, which may contain one or more hydroxyl, ether, ester groups or lactone rings; R³⁰³ is a single bond or a straight or branched C₁-C₄ alkylene group; and R³⁰⁵ is a straight, branched or cyclic C₁- C₂₀ alkyl group, which may contain one or more hydroxyl, ether, ester groups or lactone rings.

Illustrative examples of the compounds of formula (B)-1 include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine, 4,7,13,16,21,24-hexaoxa-1,10-diazabicyclo[8.8.8]hexacosane, 4,7,13,18-tetraoxa-1,10-diazabicyclo[8.5.5]eicosane, 1,4,10,13-tetraoxa-7,16-diazabicyclooctadecane, 1-aza-12-crown-4, 1-aza-15-crown-5, 1-aza-18-crown-6, tris(2-formyloxyethyl)amine, tris(2-acetoxyethyl)amine, tris(2-propionyloxyethyl)amine, tris(2-butyryloxyethyl)amine, tris(2-isobutyryloxyethyl)amine, tris(2-valeryloxyethyl)amine, tris(2-pivaloyloxyethyl)amine, N,N-bis(2-acetoxyethyl)-2-(acetoxyacetoxy)ethylamine, tris(2-methoxycarbonyloxyethyl)amine, tris(2-tert-butoxycarbonyloxyethyl)amine, tris[2-(2-oxopropoxy)ethyl]amine, tris[2-(methoxycarbonylmethyl)oxyethyl]amine, tris[2-(tert-butoxycarbonylmethyloxy)ethyl]amine, tris[2-(cyclohexyloxycarbonylmethyloxy)ethyl]amine, tris(2-methoxycarbonylethyl)amine, tris(2-ethoxycarbonylethyl)amine, N,N-bis(2-hydroxyethyl)-2-(methoxycarbonyl)ethylamine, N,N-bis(2-acetoxyethyl)-2-(methoxycarbonyl)ethylamine, N,N-bis(2-hydroxyethyl)-2-(ethoxycarbonyl)ethylamine, N,N-bis(2-acetoxyethyl)-2-(ethoxycarbonyl)ethylamine, N,N-bis(2-hydroxyethyl)-2-(2-methoxyethoxycarbonyl)ethylamine, N,N-bis(2-acetoxyethyl)-2-(2-methoxyethoxycarbonyl)ethylamine, N,N-bis(2-hydroxyethyl)-2-(2-hydroxyethoxycarbonyl)ethylamine, N,N-bis(2-acetoxyethyl)-2-(2-acetoxyethoxycarbonyl)ethylamine, N,N-bis(2-hydroxyethyl)-2-[(methoxycarbonyl)methoxycarbonyl]-ethylamine, N,N-bis(2-acetoxyethyl)-2-[(methoxycarbonyl)methoxycarbonyl]-ethylamine, N,N-bis(2-hydroxyethyl)-2-(2-oxopropoxycarbonyl)ethylamine, N,N-bis(2-acetoxyethyl)-2-(2-oxopropoxycarbonyl)ethylamine, N,N-bis(2-hydroxyethyl)-2-(tetrahydrofurfuryloxycarbonyl)-ethylamine, N,N-bis(2-acetoxyethyl)-2-(tetrahydrofurfuryloxycarbonyl)-ethylamine, N,N-bis(2-hydroxyethyl)-2-[(2-oxotetrahydrofuran-3-yl)oxy-carbonyl]ethylamine, N,N-bis(2-acetoxyethyl)-2-[(2-oxotetrahydrofuran-3-yl)oxy-carbonyl]ethylamine, N,N-bis(2-hydroxyethyl)-2-(4-hydroxybutoxycarbonyl)ethylamine, N,N-bis(2-formyloxyethyl)-2-(4-formyloxybutoxycarbonyl)-ethylamine, N,N-bis(2-formyloxyethyl)-2-(2-formyloxyethoxycarbonyl)-ethylamine, N,N-bis(2-methoxyethyl)-2-(methoxycarbonyl)ethylamine, N-(2-hydroxyethyl)-bis[2-(methoxycarbonyl)ethyl]amine, N-(2-acetoxyethyl)-bis[2-(methoxycarbonyl)ethyl]amine, N-(2-hydroxyethyl)-bis[2-(ethoxycarbonyl)ethyl]amine, N-(2-acetoxyethyl)-bis[2-(ethoxycarbonyl)ethyl]amine, N-(3-hydroxy-1-propyl)-bis[2-(methoxycarbonyl)ethyl]amine, N-(3-acetoxy-1-propyl)-bis[2-(methoxycarbonyl)ethyl]amine, N-(2-methoxyethyl)-bis[2-(methoxycarbonyl)ethyl]amine, N-butyl-bis[2-(methoxycarbonyl)ethyl]amine, N-butyl-bis[2-(2-methoxyethoxycarbonyl)ethyl]amine, N-methyl-bis(2-acetoxyethyl)amine, N-ethyl-bis(2-acetoxyethyl)amine, N-methyl-bis(2-pivaloyloxyethyl)amine, N-ethyl-bis[2-(methoxycarbonyloxy)ethyl]amine, N-ethyl-bis[2-(tert-butoxycarbonyloxy)ethyl]amine, tris(methoxycarbonylmethyl)amine, tris(ethoxycarbonylmethyl)amine, N-butyl-bis(methoxycarbonylmethyl)amine, N-hexyl-bis(methoxycarbonylmethyl)amine, and β-(diethylamino)-6-valerolactone.

Also included are one or more organic nitrogen-containing compounds having cyclic structure represented by the following general formula (B)-2.

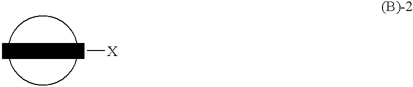

Herein X is as defined above, and R³⁰⁷ is a straight or branched C₂-C₂₀ alkylene group which may contain one or more carbonyl, ether, ester or sulfide groups.

Illustrative examples of the organic nitrogen-containing compounds having formula (B)-2 include
1-[2-(methoxymethoxy)ethyl]pyrrolidine,
1-[2-(methoxymethoxy)ethyl]piperidine,
4-[2-(methoxymethoxy)ethyl]morpholine,
1-[2-[(2-methoxyethoxy)methoxy]ethyl]pyrrolidine,
1-[2-[(2-methoxyethoxy)methoxy]ethyl]piperidine,
4-[2-[(2-methoxyethoxy)methoxy]ethyl]morpholine,
2-(1-pyrrolidinyl)ethyl acetate, 2-piperidinoethyl acetate,
2-morpholinoethyl acetate, 2-(1-pyrrolidinyl)ethyl formate,
2-piperidinoethyl propionate,
2-morpholinoethyl acetoxyacetate,
2-(1-pyrrolidinyl)ethyl methoxyacetate,
4-[2-(methoxycarbonyloxy)ethyl]morpholine,
1-[2-(t-butoxycarbonyloxy)ethyl]piperidine,
4-[2-(2-methoxyethoxycarbonyloxy)ethyl]morpholine,
methyl 3-(1-pyrrolidinyl)propionate,
methyl 3-piperidinopropionate, methyl 3-morpholinopropionate,
methyl 3-(thiomorpholino)propionate,
methyl 2-methyl-3-(1-pyrrolidinyl)propionate,
ethyl 3-morpholinopropionate,
methoxycarbonylmethyl 3-piperidinopropionate,
2-hydroxyethyl 3-(1-pyrrolidinyl)propionate,
2-acetoxyethyl 3-morpholinopropionate,
2-oxotetrahydrofuran-3-yl 3-(1-pyrrolidinyl)propionate,
tetrahydrofurfuryl 3-morpholinopropionate,
glycidyl 3-piperidinopropionate,
2-methoxyethyl 3-morpholinopropionate,
2-(2-methoxyethoxy)ethyl 3-(1-pyrrolidinyl)propionate,
butyl 3-morpholinopropionate,
cyclohexyl 3-piperidinopropionate,
α-(1-pyrrolidinyl)methyl-γ-butyrolactone,
β-piperidino-γ-butyrolactone, β-morpholino-δ-valerolactone,
methyl 1-pyrrolidinylacetate, methyl piperidinoacetate,
methyl morpholinoacetate, methyl thiomorpholinoacetate,
ethyl 1-pyrrolidinylacetate, 2-methoxyethyl morpholinoacetate,
2-morpholinoethyl 2-methoxyacetate,
2-morpholinoethyl 2-(2-methoxyethoxy)acetate,
2-morpholinoethyl 2-[2-(2-methoxyethoxy)ethoxy]acetate,
2-morpholinoethyl hexanoate, 2-morpholinoethyl octanoate,
2-morpholinoethyl decanoate, 2-morpholinoethyl laurate,
2-morpholinoethyl myristate, 2-morpholinoethyl palmitate, and
2-morpholinoethyl stearate.

Also, one or more organic nitrogen-containing compounds having cyano group represented by the following general formulae (B)-3 to (B)-6 be included.

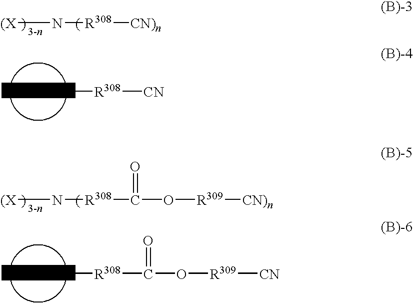

Herein, X, R³⁰⁷ and n are as defined above, and R³⁰⁸ and R³⁰⁹ are each independently a straight or branched C₁-C₄ alkylene group.

Illustrative examples of the organic nitrogen-containing compounds having cyano represented by formulae (B)-3 to (B)-6 include
3-(diethylamino)propiononitrile,
N,N-bis(2-hydroxyethyl)-3-aminopropiononitrile,
N,N-bis(2-acetoxyethyl)-3-aminopropiononitrile,
N,N-bis(2-formyloxyethyl)-3-aminopropiononitrile,
N,N-bis(2-methoxyethyl)-3-aminopropiononitrile,
N,N-bis[2-(methoxymethoxy)ethyl]-3-aminopropiononitrile,
methyl N-(2-cyanoethyl)-N-(2-methoxyethyl)-3-aminopropionate,
methyl N-(2-cyanoethyl)-N-(2-hydroxyethyl)-3-aminopropionate,
methyl N-(2-acetoxyethyl)-N-(2-cyanoethyl)-3-aminopropionate,
N-(2-cyanoethyl)-N-ethyl-3-aminopropiononitrile,
N-(2-cyanoethyl)-N-(2-hydroxyethyl)-3-aminopropiononitrile,
N-(2-acetoxyethyl)-N-(2-cyanoethyl)-3-aminopropiononitrile,
N-(2-cyanoethyl)-N-(2-formyloxyethyl)-3-aminopropiononitrile,
N-(2-cyanoethyl)-N-(2-methoxyethyl)-3-aminopropiononitrile,
N-(2-cyanoethyl)-N-[2-(methoxymethoxy)ethyl]-3-aminopropiono-nitrile,
N-(2-cyanoethyl)-N-(3-hydroxy-1-propyl)-3-aminopropiononitrile,
N-(3-acetoxy-1-propyl)-N-(2-cyanoethyl)-3-aminopropiononitrile,
N-(2-cyanoethyl)-N-(3-formyloxy-1-propyl)-3-aminopropiono-nitrile,
N-(2-cyanoethyl)-N-tetrahydrofurfuryl-3-aminopropiononitrile,
N,N-bis(2-cyanoethyl)-3-aminopropiononitrile,
diethylaminoacetonitrile,
N,N-bis(2-hydroxyethyl)aminoacetonitrile,
N,N-bis(2-acetoxyethyl)aminoacetonitrile,
N,N-bis(2-formyloxyethyl)aminoacetonitrile,
N,N-bis(2-methoxyethyl)aminoacetonitrile,
N,N-bis[2-(methoxymethoxy)ethyl]aminoacetonitrile,
methyl N-cyanomethyl-N-(2-methoxyethyl)-3-aminopropionate,
methyl N-cyanomethyl-N-(2-hydroxyethyl)-3-aminopropionate,
methyl N-(2-acetoxyethyl)-N-cyanomethyl-3-aminopropionate,
N-cyanomethyl-N-(2-hydroxyethyl)aminoacetonitrile,
N-(2-acetoxyethyl)-N-(cyanomethyl)aminoacetonitrile,
N-cyanomethyl-N-(2-formyloxyethyl)aminoacetonitrile,
N-cyanomethyl-N-(2-methoxyethyl)aminoacetonitrile,
N-cyanomethyl-N-[2-(methoxymethoxy)ethyl)aminoacetonitrile,
N-cyanomethyl-N-(3-hydroxy-1-propyl)aminoacetonitrile,
N-(3-acetoxy-1-propyl)-N-(cyanomethyl)aminoacetonitrile,
N-cyanomethyl-N-(3-formyloxy-1-propyl)aminoacetonitrile,
N,N-bis(cyanomethyl)aminoacetonitrile,
1-pyrrolidinepropiononitrile, 1-piperidinepropiononitrile,
4-morpholinepropiononitrile, 1-pyrrolidineacetonitrile,
1-piperidineacetonitrile, 4-morpholineacetonitrile,
cyanomethyl 3-diethylaminopropionate,
cyanomethyl N,N-bis(2-hydroxyethyl)-3-aminopropionate,
cyanomethyl N,N-bis(2-acetoxyethyl)-3-aminopropionate,
cyanomethyl N,N-bis(2-formyloxyethyl)-3-aminopropionate,
cyanomethyl N,N-bis(2-methoxyethyl)-3-aminopropionate,
cyanomethyl N,N-bis[2-(methoxymethoxy)ethyl]-3-aminopropionate,
2-cyanoethyl 3-diethylaminopropionate,
2-cyanoethyl N,N-bis(2-hydroxyethyl)-3-aminopropionate,
2-cyanoethyl N,N-bis(2-acetoxyethyl)-3-aminopropionate,
2-cyanoethyl N,N-bis(2-formyloxyethyl)-3-aminopropionate,
2-cyanoethyl N,N-bis(2-methoxyethyl)-3-aminopropionate,
2-cyanoethyl N,N-bis[2-(methoxymethoxy)ethyl]-3-amino-propionate,
cyanomethyl 1-pyrrolidinepropionate,
cyanomethyl 1-piperidinepropionate,
cyanomethyl 4-morpholinepropionate,
2-cyanoethyl 1-pyrrolidinepropionate,
2-cyanoethyl 1-piperidinepropionate, and
2-cyanoethyl 4-morpholinepropionate.

Also included are organic nitrogen-containing compounds having an imidazole structure and a polar functional group, represented by the general formula (B)-7.

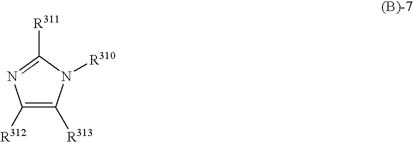

Herein, R³¹⁶ is a straight, branched or cyclic alkyl group of 2 to 20 carbon atoms bearing at least one polar functional group selected from among hydroxyl, carbonyl, ester, ether, sulfide, carbonate, cyano and acetal groups; R³¹¹, R³¹² and R³¹³ are each independently a hydrogen atom, a straight, branched or cyclic alkyl group, aryl group or aralkyl group having 1 to 10 carbon atoms.

Also included are organic nitrogen-containing compounds having a benzimidazole structure and a polar functional group, represented by the general formula (B)-8.

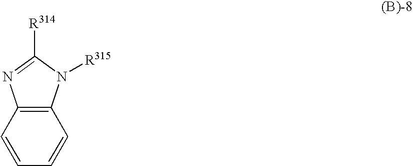

Herein, R³¹⁴ is a hydrogen atom, a straight, branched or cyclic alkyl group, aryl group or aralkyl group having 1 to 10 carbon atoms. R³¹⁵ is a polar functional group-bearing, straight, branched or cyclic alkyl group of 1 to 20 carbon atoms, and the alkyl group contains as the polar functional group at least one group selected from among ester, acetal and cyano groups, and may additionally contain at least one group selected from among hydroxyl, carbonyl, ether, sulfide and carbonate groups.

Further included are heterocyclic nitrogen-containing compounds having a polar functional group, represented by the general formulae (B)-9 and (B)-10.

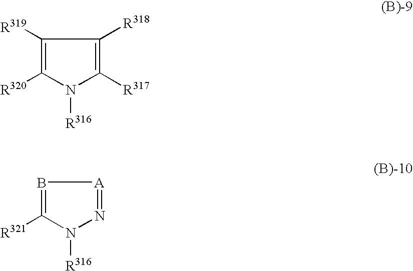

Herein, A is a nitrogen atom or ≡C—R³²², B is a nitrogen atom or ≡C—R³²³, R³¹⁶ is a straight, branched or cyclic alkyl group of 2 to 20 carbon atoms bearing at least one polar functional group selected from among hydroxyl, carbonyl, ester, ether, sulfide, carbonate, cyano and acetal groups; R³¹⁷ , R³¹⁸, R³¹⁹ and R³²⁰ are each independently a hydrogen atom, a straight, branched or cyclic alkyl group or aryl group having 1 to 10 carbon atoms, or a pair of R³¹⁷ and R³¹⁸ and a pair of R³¹⁹ and R³²⁰ may bond together to form a benzene, naphthalene or pyridine ring with the carbon atom to which they are attached; R³²¹ is a hydrogen atom, a straight, branched or cyclic alkyl group or aryl group having 1 to 10 carbon atoms; R³²² and R³²³ each are a hydrogen atom, a straight, branched or cyclic alkyl group or aryl group having 1 to 10 carbon atoms, or a pair of R³²¹ and R³²³, taken together, may form a benzene or naphthalene ring with the carbon atoms to which they are attached.

Also included are organic nitrogen-containing compounds of aromatic carboxylic ester structure having the general formulae (B)-11 to (B)-14.

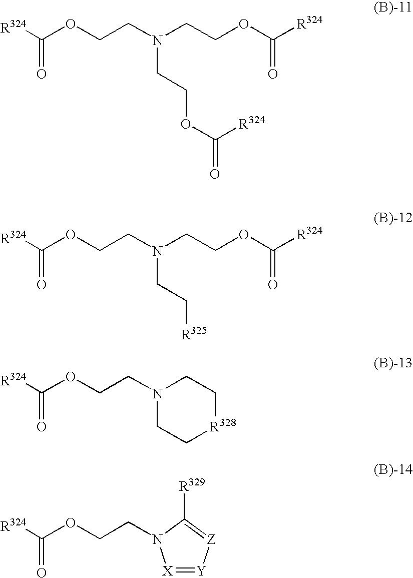

Herein R³²⁴ is a C₆-C₂₀ aryl group or C₄-C₂₀ hetero-aromatic group, in which some or all of hydrogen atoms may be replaced by halogen atoms, straight, branched or cyclic C₁-C₂₀ alkyl groups, C₆-C₂₀ aryl groups, C₇-C₂₀ aralkyl groups, C₁-C₁₀ alkoxy groups, C₁-C₁₀ acyloxy groups or C₁-C₁₀ alkylthio groups. R³²⁵ is CO₂R³²⁶, OR³²⁷ or cyano group. R³²⁶ is a C₁-C₁₀ alkyl group, in which some methylene groups may be replaced by oxygen atoms. R³²⁷ is a C₁-C₁₀ alkyl or acyl group, in which some methylene groups may be replaced by oxygen atoms. R³²⁸ is a single bond, methylene, ethylene, sulfur atom or —O(CH₂CH₂O)ₙ-group wherein n is 0, 1, 2, 3 or 4. R³²⁹ is hydrogen, methyl, ethyl or phenyl. X is a nitrogen atom or CR³³⁰. Y is a nitrogen atom or CR³³¹. Z is a nitrogen atom or CR³³². R³³⁰, R³³¹ and R³³² are each independently hydrogen, methyl or phenyl. Alternatively, a pair of R³³⁰ and R³³¹ or a pair of R³³¹ and R³³² may bond together to form a C₆-C₂₀ aromatic ring or C₂-C₂₀ hetero-aromatic ring with the carbon atoms to which they are attached.

Further included are organic nitrogen-containing compounds of 7-oxanorbornane-2-carboxylic ester structure having the general formula (B)-15.

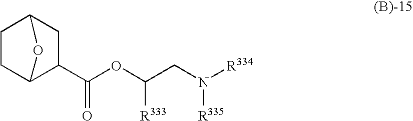

Herein R³³³ is hydrogen or a straight, branched or cyclic C₁-C₁₀ alkyl group. R³³⁴ and R³³⁵ are each independently a C₁-C₂₀ alkyl group, C₆-C₂₀ aryl group or C₇-C₂₀ aralkyl group, which may contain one or more polar functional groups selected from among ether, carbonyl, ester, alcohol, sulfide, nitrile, amine, imine, and amide and in which some hydrogen atoms may be replaced by halogen atoms. R³³⁴ and R³³⁵, taken together, may form a heterocyclic or hetero-aromatic ring of 2 to 20 carbon atoms with the nitrogen atom to which they are attached.

The nitrogen-containing compounds may be used alone or in admixture of two or more. The nitrogen-containing compound (C) is preferably formulated in an amount of 0.01 to 2 parts, and especially 0.01 to 1 part by weight, per 100 parts by weight of the base resin (A). Less amounts of the nitrogen-containing compound achieve no or little addition effect whereas excessive amounts may result in too low a sensitivity.

The resist composition of the invention may include optional ingredients, for example, known dissolution inhibitors, surfactants, acidic compounds, dyes, thermal crosslinkers, and stabilizers.

Illustrative, non-limiting, examples of the surfactant include nonionic surfactants, for example, polyoxyethylene alkyl ethers such as polyoxyethylene lauryl ether, polyoxyethylene stearyl ether, polyoxyethylene cetyl ether, and polyoxyethylene oleyl ether, polyoxyethylene alkylaryl ethers such as polyoxyethylene octylphenol ether and polyoxyethylene nonylphenol ether, polyoxyethylene polyoxypropylene block copolymers, sorbitan fatty acid esters such as sorbitan monolaurate, sorbitan monopalmitate, and sorbitan monostearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorochemical surfactants such as EFTOP EF301, EF303 and EF352 (Tohkem Products Co., Ltd.), Megaface F171, F172 and F173 (Dainippon Ink & Chemicals, Inc.), Fluorad FC430 and FC431 (Sumitomo 3M Co., Ltd.), Asahiguard AG710, Surflon S-381, S-382, SC101, SC102, SC103, SC104, SC105, SC106, Surfynol E1004, KH-10, KH-20, KH-30 and KH-40 (Asahi Glass Co., Ltd.); organosiloxane polymers KP341, X-70-092 and X-70-093 (Shin-Etsu Chemical Co., Ltd.), acrylic acid or methacrylic acid Polyflow No. 75 and No. 95 (Kyoeisha Yushi Kagaku Kogyo K.K.). Inter alia, Fluorad FC430, Surflon S-381, Surfynol E1004, KH-20 and KH-30 are preferred. These surfactants may be used alone or in admixture.

In the resist composition, the surfactant is preferably formulated in an amount of up to 2 parts, and especially up to 1 part by weight, per 100 parts by weight of the base resin.

### Process

The resist composition of the invention is used to form a resist film on a processable substrate (or substrate to be processed). The process includes the steps of coating the resist composition onto the processable substrate and prebaking. These steps may be performed by well-known techniques. Depending on a particular purpose, a resist film having a thickness in the range of 10 to 2,000 nm may be formed.

The coating step may be performed by spin coating and several other known techniques. Where a resist film having a thickness of about 150 nm or less is formed, spin coating is most preferred to achieve a uniform film thickness.

Where the processable substrate is a semiconductor wafer, spin coating conditions must be adjusted in accordance with the wafer size, the desired film thickness, the composition of resist, and the like. In an example wherein a resist film having a thickness of about 100 nm is formed on a 8-inch wafer, the resist composition is cast on the wafer, after which the wafer is spun at 4,000 to 5,000 rpm for 40 seconds. Then a resist film featuring uniformity is obtained. In this example, the amount of the solvent mixture used in the preparation of the resist composition is preferably 1,400 to 1,600 parts by weight per 100 parts by weight of the base resin. The resist coating thus applied is then prebaked in order to remove the excess solvent remaining in the coating. The prebaking is preferably performed, for example, on a hot plate at a temperature of 80 to 130° C. for 1 to 10 minutes, more preferably at 90 to 110° C. for 3 to 5 minutes.

Where the processable substrate is a photomask blank, coating conditions must also be adjusted in accordance with the blank size, the desired film thickness, the composition of resist, and the like. In an example wherein a resist film having a thickness of about 100 nm is formed on a square blank of 15.2 cm×15.2 cm, the resist composition is cast on the blank, after which the blank is spun at 1,500 to 3,000 rpm for 2 seconds and then at or below 800 rpm for 30 seconds. Then a resist film featuring uniformity is obtained. In this example, the amount of the solvent mixture used in the preparation of the resist composition is preferably 2,000 to 2,700 parts by weight per 100 parts by weight of the base resin. The resist coating thus applied is then prebaked in order to remove the excess solvent remaining in the coating. The prebaking is preferably performed, for example, on a hot plate at a temperature of 80 to 130° C. for 4 to 20 minutes, more preferably at 90 to 110° C. for 8 to 12 minutes.

Next, the resist film thus formed is subjected to patternwise exposure to form the desired pattern. In the case of semiconductor processing, exposure may be performed by placing a mask having the desired pattern over the resist film, and irradiating high-energy radiation (e.g., deep UV, excimer laser or x-ray) or electron beam (EB) so as to give an exposure dose of 1 to 100 μC/cm², preferably 10 to 100 μC/cm². The exposure may be performed by standard lithography or if desired, by immersion lithography of filling a liquid between the projection lens and the resist film.

Where a photomask blank is processed, the patternwise exposure is generally beam exposure because this processing does not aim to produce a number of identical parts. The high-energy radiation used herein is typically electron beam although any radiation from other light sources may be similarly used as long as the radiation is collected into a beam.

Following the exposure, the resist film is typically baked in order to cause the acid to diffuse to induce chemical amplifying reaction. The post-exposure baking (PEB) is preferably performed, for example, on a hot plate at a temperature of 60 to 150° C. for 0.1 to 5 minutes, more preferably at 80 to 140° C. for 0.5 to 3 minutes. The resist film is then developed with a developer in the form of an aqueous alkaline solution, typically a 0.1 to 5 wt %, preferably 2 to 3 wt % aqueous solution of tetramethylammonium hydroxide (TMAH) for 0.1 to 3 minutes, preferably 0.5 to 2 minutes by a standard technique such as dip, puddle or spray technique. In this way, the desired pattern is formed on the substrate. If necessary, the development may be followed by further heat treatment (known as thermal flow) to tailor the pattern size. The resist composition of the invention is best suited in nano-scale patterning using selected high-energy radiation such as deep-UV or excimer laser having a wavelength 250 to 120 nm, EUV, x-ray or electron beam.

### EXAMPLE

Examples and Comparative Examples are given below by way of illustration and not by way of limitation.

The components used in the resist compositions are identified below. Base polymers (Polymer-1, 2) and acid generators (PAG-1, 2) have the structural formula shown below. The weight average molecular weight (Mw) and number average molecular weight (Mn) are determined by gel permeation chromatography (GPC) versus polystyrene standards.

| | |
|---|---|
| 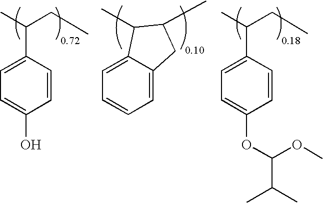 | Polymer-1 Mw 14,000 Mw/Mn 1.70 |
| 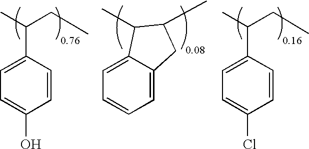 | Polymer-2 Mw 4,200 Mw/Mn 1.59 |
| 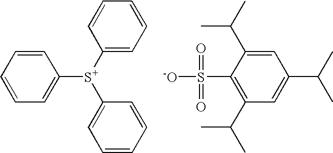 | PAG-1 |
| 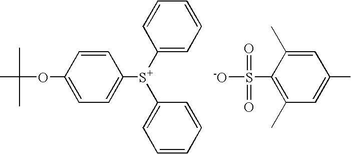 | PAG-2 |

| | |
|---|---|
| Solvent A: | propylene glycol monomethyl ether acetate |
| | (PGMEA) |
| Solvent B: | propylene glycol monomethyl ether (PGME) |
| Solvent C: | ethyl lactate (EL) |
| N-containing compound A: | tris(2-(methoxymethoxy)ethyl)amine |
| N-containing compound B: | oxidized tris(2-(methoxymethoxy)- |
| | ethyl)amine |
| Surfactant A: | KH-20 (Asahi Glass Co., Ltd.) |
| Crosslinker A: | hexamethoxymethylglycoluril |

### Example 1 and Comparative Examples 1-3

Chemically amplified positive resist compositions were prepared in accordance with the formulation of Table 1 using solvent mixtures. The pattern forming process of the invention was implemented using the compositions, and the resulting patterns were evaluated for resolution and profile.

TABLE 1

| | Example | Comparative Example | | |
|---|---|---|---|---|
| Components, pbw | 1 | 1 | 2 | 3 |
| Polymer-1 | 80 | 80 | 80 | 80 |
| PAG-1 | 6 | 6 | 6 | 6 |
| PAG-2 | 2 | 2 | 2 | 2 |
| PGMEA | 1,400 | 1,000 | 1,400 | 1,400 |
| EL | 600 | 1,000 | | — |
| PGME | — | — | 600 | 600 |
| γ-butyrolactone | 160 | — | — | 160 |
| Surfactant A | 0.07 | 0.07 | 0.07 | 0.07 |
| N-containing compound | 0.3 | 0.3 | 0.3 | 0.3 |
| A | | | | |
| N-containing compound | 0.3 | 0.3 | 0.3 | 0.3 |
| B | | | | |

The resist compositions were filtered through a 0.04-μm nylon resin filter and then spin-coated onto mask blanks of 152 mm square having an outermost surface of chromium oxynitride to a thickness of 150 nm. The coating conditions included: 1,000 rpm×1 sec, 2,500 rpm×1.5 sec, 800 rpm×5 sec, 100 rpm×30 sec, and 2,000 rpm×30 sec. The coated mask blanks were baked on a hot plate at 90° C. for 10 minutes.

The film thickness was measured by an optical film thickness measurement system NanoSpec (Nanometrics Inc.). Measurement was carried out at 81 in-plane points on the blank substrate excluding an outer rim portion extending 10 mm inward from the blank circumference. From these measurements, an average film thickness and a film thickness range were determined.

Then, using an EB mask writer EBM5000 (NuFLARE Technology Inc., accelerating voltage 50 keV), the resist films were exposed. They were baked (PEB) at 110° C. for 10 minutes, and developed with a 2.38 wt % aqueous solution of TMAH, obtaining positive patterns (Example 1, Comparative Examples 1-3).

The resulting resist patterns were evaluated as follows.

The optimum exposure dose (sensitivity Eop) was the exposure dose which provided a 1:1 resolution at the top and bottom of a 200-nm line-and-space pattern. The minimum line width (nm) of a line-and-space pattern which was ascertained separate on the mask blank when processed at the optimum dose was the resolution of a test resist. The shape in cross section of the resolved resist pattern was observed under a scanning electron microscope (SEM).

For line edge roughness (LER), deviations were measured at 50 points in a longitudinal 5-μm region of a 100-nm line, using measurement SEM (S-8840 by Hitachi, Ltd.). A value of 3σ was computed, with smaller values indicating better performance.

Coating property was evaluated based on the film thickness range. For the evaluation of storage stability, the resist composition as prepared was kept in a light-shielding vessel in an air-unshielded atmosphere for one month. Thereafter, a resist pattern was similarly formed from the aged resist composition. A change of optimum dose (sensitivity Eop) for the 200-nm line-and-space pattern was determined. The sample was rated passed (◯) or rejected (×) whether or not the change of optimum dose was within 5%.

Table 2 reports the test results of resolution, profile (cross-sectional shape), LER, storage stability, and coating property.

TABLE 2

| | | | | | Film |
|---|---|---|---|---|---|
| | | | | Storage | thickness |
| | | | LER, | stability | range, |
| | Resolution, nm | Profile | nm | (1 month) | nm |
| Example 1 | 50 | rectangular | 3 | ◯ | 3 |
| Comparative Example 1 | 50 | rectangular | 3 | X | 3 |
| Comparative Example 2 | 50 | rectangular | 6 | ◯ | 6 |
| Comparative Example 3 | 50 | rectangular | 5 | ◯ | 4 |

The above results demonstrate that Example 1 established storage stability while maintaining resolution and film formation, in contrast to Comparative Example 1 which lacked storage stability due to a larger proportion of EL. In Comparative Example 2 using only PGMEA and PGME, film formation was unsatisfactory, and LER increased due to development of coarse micro-domains. Comparative Example 3 which was intended to improve over Comparative Example 2 by adding a high-boiling solvent, γ-butyrolactone, failed to provide a fully improved value of LER.

### Examples 2-7

As in Example 1, resist compositions were prepared in accordance with the formulation of Table 3. The high-boiling solvent in Example 1 was replaced by tert-butyl acetoacetate, dipropylene glycol methyl ether acetate, dipropylene glycol butyl ether, tripropylene glycol butyl ether, ethylene carbonate, and propylene carbonate. Pattern formation was carried out as in Example 1 by spin coating the resist solution onto a mask blank. The resulting patterns were evaluated for resolution and profile.

Table 4 reports the test results of resolution, profile (cross-sectional shape), LER, storage stability, and coating property.

TABLE 3

| | Example | | | | | |
|---|---|---|---|---|---|---|
| Components, pbw | 2 | 3 | 4 | 5 | 6 | 7 |
| Polymer-1 | 80 | 80 | 80 | 80 | 80 | 80 |
| PAG-1 | 6 | 6 | 6 | 6 | 6 | 6 |
| PAG-2 | 2 | 2 | 2 | 2 | 2 | 2 |
| PGMEA | 1,400 | 1,400 | 1,400 | 1,400 | 1,400 | 1,400 |
| EL | 600 | 600 | 600 | 600 | 600 | 600 |
| γ-butyrolactone | — | — | — | — | — | — |
| tert-butyl acetoacetate | 160 | — | — | — | — | — |
| dipropylene glycol methyl ether acetate | — | 160 | — | — | — | — |
| dipropylene glycol butyl ether | — | — | 160 | — | — | — |
| tripropylene glycol butyl ether | — | — | — | 160 | — | — |
| ethylene carbonate | — | — | — | — | 160 | — |
| propylene carbonate | — | — | — | — | — | 160 |
| Surfactant A | 0.07 | 0.07 | 0.07 | 0.07 | 0.07 | 0.07 |
| N-containing compound A | 0.3 | 0.3 | 0.3 | 0.3 | 0.3 | 0.3 |
| N-containing compound B | 0.3 | 0.3 | 0.3 | 0.3 | 0.3 | 0.3 |

TABLE 4

| | | | | | Film |
|---|---|---|---|---|---|
| | | | | Storage | thickness |
| | Resolution, | | LER, | stability | range, |
| | nm | Profile | nm | (1 month) | nm |
| Example 2 | 50 | rectangular | 3 | ◯ | 4 |
| Example 3 | 50 | rectangular | 2 | ◯ | 3 |
| Example 4 | 50 | rectangular | 2 | ◯ | 3 |
| Example 5 | 50 | rectangular | 2 | ◯ | 3 |
| Example 6 | 50 | rectangular | 3 | ◯ | 3 |
| Example 7 | 50 | rectangular | 3 | ◯ | 3 |

The above results demonstrate that even when the high-boiling solvent in Example 1 is replaced by tert-butyl acetoacetate, dipropylene glycol methyl ether acetate, dipropylene glycol butyl ether, tripropylene glycol butyl ether, ethylene carbonate, and propylene carbonate, the resist compositions have storage stability, effective coating, and improved LER as in Example 1.

### Examples 8-14

As in Example 1, resist compositions were prepared in accordance with the formulation of Table 5. To the resist compositions of Examples 1-7, propylene glycol monomethyl ether (PGME) was added as the fourth solvent. Pattern formation was carried out as in Example 1 by spin coating the resist solution onto a mask blank. The resulting patterns were evaluated for resolution and profile.

Table 6 reports the test results of resolution, profile (cross-sectional shape), LER, storage stability, and coating property.

TABLE 5

| | Example | | | | | | |
|---|---|---|---|---|---|---|---|
| Components, pbw | 8 | 9 | 10 | 11 | 12 | 13 | 14 |
| Polymer-1 | 80 | 80 | 80 | 80 | 80 | 80 | 80 |
| PAG-1 | 6 | 6 | 6 | 6 | 6 | 6 | 6 |
| PAG-2 | 2 | 2 | 2 | 2 | 2 | 2 | 2 |
| PGMEA | 900 | 900 | 900 | 900 | 900 | 900 | 900 |
| EL | 600 | 600 | 600 | 600 | 600 | 600 | 600 |
| PGME | 600 | 600 | 600 | 600 | 600 | 600 | 600 |
| γ-butyrolactone | 160 | — | — | — | — | — | — |
| tert-butyl acetoacetate | — | 160 | — | — | — | — | — |
| dipropylene glycol methyl ether | — | — | 160 | — | — | — | — |
| acetate | | | | | | | |
| dipropylene glycol butyl ether | — | — | — | 160 | — | — | — |
| tripropylene glycol butyl ether | — | — | — | — | 160 | — | — |
| ethylene carbonate | — | — | — | — | — | 160 | — |
| propylene carbonate | — | — | — | — | — | — | 160 |
| Surfactant A | 0.07 | 0.07 | 0.07 | 0.07 | 0.07 | 0.07 | 0.07 |
| N-containing compound A | 0.3 | 0.3 | 0.3 | 0.3 | 0.3 | 0.3 | 0.3 |
| N-containing compound B | 0.3 | 0.3 | 0.3 | 0.3 | 0.3 | 0.3 | 0.3 |

TABLE 6

| | | | | | Film |
|---|---|---|---|---|---|
| | | | | Storage | thickness |
| | Resolution, | | LER, | stability | range, |
| | nm | Profile | nm | (1 month) | nm |
| Example 8 | 50 | rectangular | 3 | ◯ | 4 |
| Example 9 | 50 | rectangular | 3 | ◯ | 4 |
| Example 10 | 50 | rectangular | 2 | ◯ | 3 |
| Example 11 | 50 | rectangular | 2 | ◯ | 3 |
| Example 12 | 50 | rectangular | 2 | ◯ | 3 |
| Example 13 | 50 | rectangular | 3 | ◯ | 3 |
| Example 14 | 50 | rectangular | 3 | ◯ | 3 |

The above results demonstrate that the resist compositions to which PGME is added as the fourth solvent have desired storage stability, effective coating, and improved LER as long as a weight proportion of PGMEA is the highest among the solvents, EL accounts for 10-40 wt % based on the total solvent weight, and the third solvent selected from γ-butyrolactone, alkyl acetoacetate, dipropylene glycol methyl ether acetate, dipropylene glycol butyl ether, tripropylene glycol butyl ether, ethylene carbonate, and propylene carbonate accounts for 0.2-10 wt % based on the total solvent weight.

### Examples 15-21

For the purpose of facilitating formation of thinner films, resist compositions were prepared in accordance with the formulation of Table 7. Pattern formation was carried out as in Example 1 by spin coating the resist solution onto a mask blank. Since the resist compositions had a lower concentration, the films formed by coating had a thickness of 90 nm despite the same coating conditions as in Example 1. The resulting patterns were evaluated for resolution and profile.

Table 8 reports the test results of resolution, profile (cross-sectional shape), LER, storage stability, and coating property. The thinner film permitted resolution of a 40 nm pattern without collapse.

TABLE 7

| | Example | | | | | | |
|---|---|---|---|---|---|---|---|
| Components, pbw | 15 | 16 | 17 | 18 | 19 | 20 | 21 |
| Polymer-1 | 80 | 80 | 80 | 80 | 80 | 80 | 80 |
| PAG-1 | 6 | 6 | 6 | 6 | 6 | 6 | 6 |
| PAG-2 | 2 | 2 | 2 | 2 | 2 | 2 | 2 |
| PGMEA | 1,200 | 1,200 | 1,200 | 1,200 | 1,200 | 1,200 | 1,200 |
| EL | 700 | 700 | 700 | 700 | 700 | 700 | 700 |
| PGME | 800 | 800 | 800 | 800 | 800 | 800 | 800 |
| γ-butyrolactone | 180 | — | — | — | — | — | — |
| tert-butyl acetoacetate | — | 180 | — | — | — | — | — |
| dipropylene glycol methyl ether | — | — | 180 | — | — | — | — |
| acetate | | | | | | | |
| dipropylene glycol butyl ether | — | — | — | 180 | — | — | — |
| tripropylene glycol butyl ether | — | — | — | — | 180 | — | — |
| ethylene carbonate | — | — | — | — | — | 180 | — |
| propylene carbonate | — | — | — | — | — | — | 180 |
| Surfactant A | 0.07 | 0.07 | 0.07 | 0.07 | 0.07 | 0.07 | 0.07 |
| N-containing compound A | 0.3 | 0.3 | 0.3 | 0.3 | 0.3 | 0.3 | 0.3 |
| N-containing compound B | 0.3 | 0.3 | 0.3 | 0.3 | 0.3 | 0.3 | 0.3 |

TABLE 8

| | | | | | Film |
|---|---|---|---|---|---|
| | | | | Storage | thickness |
| | Resolution, | | LER, | stability | range, |
| | nm | Profile | nm | (1 month) | nm |
| Example 15 | 40 | rectangular | 4 | ◯ | 4 |
| Example 16 | 40 | rectangular | 4 | ◯ | 4 |
| Example 17 | 40 | rectangular | 2 | ◯ | 3 |
| Example 18 | 40 | rectangular | 2 | ◯ | 3 |
| Example 19 | 40 | rectangular | 2 | ◯ | 3 |
| Example 20 | 40 | rectangular | 4 | ◯ | 4 |
| Example 21 | 40 | rectangular | 3 | ◯ | 4 |

Prior art resist compositions having storage stability suffer from the problems of inefficient coating and increased LER when thin films have to be formed therefrom. In contrast, the above results demonstrate that the resist compositions within the scope of the invention are effectively coated and improved in LER even when thin films having a thickness of less than 100 nm are formed therefrom.

### Examples 22-26 and Comparative Examples 4-5

For the purpose of evaluating resolution and LER versus the content of dipropylene glycol methyl ether acetate, resist compositions were prepared in accordance with the formulation of Table 9. Pattern formation was carried out as in Example 1 by spin coating the resist solution onto a mask blank. The resulting patterns were evaluated for resolution and profile.

Table 10 reports the test results of resolution, profile (cross-sectional shape), LER, storage stability, and coating property.

TABLE 9

| | | | | | | | Comparative | |
|---|---|---|---|---|---|---|---|---|
| | Example | | | | | | Example | |
| Components, pbw | 3 | 22 | 23 | 24 | 25 | 26 | 4 | 5 |
| Polymer-1 | 80 | 80 | 80 | 80 | 80 | 80 | 80 | 80 |
| PAG-1 | 6 | 6 | 6 | 6 | 6 | 6 | 6 | 6 |
| PAG-2 | 2 | 2 | 2 | 2 | 2 | 2 | 2 | 2 |
| PGMEA | 1,400 | 1,400 | 1,400 | 1,400 | 1,400 | 1,400 | 1,400 | 1,400 |
| EL | 600 | 600 | 600 | 600 | 600 | 600 | 600 | 600 |
| dipropylene glycol | 160 | 80 | 240 | 320 | 400 | 480 | 20 | 560 |
| methyl ether acetate | | | | | | | | |
| Surfactant A | 0.07 | 0.07 | 0.07 | 0.07 | 0.07 | 0.07 | 0.07 | 0.07 |
| N-containing compound A | 0.3 | 0.3 | 0.3 | 0.3 | 0.3 | 0.3 | 0.3 | 0.3 |
| N-containing compound B | 0.3 | 0.3 | 0.3 | 0.3 | 0.3 | 0.3 | 0.3 | 0.3 |

TABLE 10

| | | | | | Film |
|---|---|---|---|---|---|
| | | | | Storage | thickness |
| | Resolution, | | LER, | stability | range, |
| | nm | Profile | nm | (1 month) | nm |
| Example 3 | 50 | rectangular | 2 | ◯ | 3 |
| Example 22 | 50 | rectangular | 4 | ◯ | 4 |
| Example 23 | 50 | rectangular | 3 | ◯ | 3 |
| Example 24 | 50 | rectangular | 2 | ◯ | 3 |
| Example 25 | 50 | rectangular | 2 | ◯ | 3 |
| Example 26 | 50 | rectangular | 2 | ◯ | 5 |
| Comparative | 50 | rectangular | 5 | ◯ | 6 |
| Example 4 | | | | | |
| Comparative | 50 | constricted | 3 | ◯ | 6 |
| Example 5 | | | | | |

The above results demonstrate that outstanding LER improving effects and satisfactory resist pattern profiles are obtained when the amount of high-boiling solvent added is in the range of 0.2 wt % to 20 wt % based on the total solvent weight.

### Examples 27-33 and Comparative Example 6

Chemically amplified negative resist compositions were prepared in accordance with the formulation of Table 11, using solvent mixtures within the scope of the invention. Pattern formation was carried out as in Example 1 by spin coating the resist solution onto a mask blank. The resulting patterns were evaluated for resolution and profile.

Table 12 reports the test results of resolution, profile (cross-sectional shape), LER, storage stability, and coating property.

TABLE 11

| | | | | | | | | Comparative |
|---|---|---|---|---|---|---|---|---|
| | Example | | | | | | | Example |
| Components, pbw | 27 | 28 | 29 | 30 | 31 | 32 | 33 | 6 |
| Polymer-2 | 80 | 80 | 80 | 80 | 80 | 80 | 80 | 80 |
| PAG-1 | 8 | 8 | 8 | 8 | 8 | 8 | 8 | 8 |
| PAG-2 | 2 | 2 | 2 | 2 | 2 | 2 | 2 | 2 |
| Crosslinker A | 8.2 | 8.2 | 8.2 | 8.2 | 8.2 | 8.2 | 8.2 | 8.2 |
| PGMEA | 1,400 | 1,400 | 1,400 | 1,400 | 1,400 | 1,400 | 1,400 | 1,400 |
| EL | 600 | 600 | 600 | 600 | 600 | 600 | 600 | — |
| PGME | — | — | — | — | — | — | — | 600 |
| γ-butyrolactone | 180 | — | — | — | — | — | — | 180 |
| tert-butyl acetoacetate | — | 180 | — | — | — | — | — | — |
| dipropylene glycol | — | — | 180 | — | — | — | — | — |
| methyl ether acetate | | | | | | | | |
| dipropylene glycol butyl | — | — | — | 180 | — | — | — | — |
| ether | | | | | | | | |
| tripropylene glycol | — | — | — | — | 180 | — | — | — |
| butyl ether | | | | | | | | |
| ethylene carbonate | — | — | — | — | — | 180 | — | — |
| propylene carbonate | — | — | — | — | — | — | 180 | — |
| Surfactant A | 0.07 | 0.07 | 0.07 | 0.07 | 0.07 | 0.07 | 0.07 | 0.07 |
| N-containing compound A | 0.33 | 0.33 | 0.33 | 0.33 | 0.33 | 0.33 | 0.33 | 0.33 |

TABLE 12

| | | | | | Film |
|---|---|---|---|---|---|
| | | | | Storage | thickness |
| | Resolution, | | LER, | stability | range, |
| | nm | Profile | nm | (1 month) | nm |
| Example 27 | 50 | rectangular | 3 | ◯ | 4 |
| Example 28 | 50 | rectangular | 3 | ◯ | 4 |
| Example 29 | 50 | rectangular | 2 | ◯ | 3 |
| Example 30 | 50 | rectangular | 2 | ◯ | 3 |
| Example 31 | 50 | rectangular | 2 | ◯ | 3 |
| Example 32 | 50 | rectangular | 3 | ◯ | 4 |
| Example 33 | 50 | rectangular | 3 | ◯ | 4 |
| Comparative | 50 | rectangular | 5 | ◯ | 6 |
| Example 6 | | | | | |

The above results demonstrate that like the positive resist compositions, chemically amplified negative resist compositions have desired storage stability, effective coating, and improved LER when solvent mixtures within the scope of the invention are used.

### Experiment

Quantitative determination of residual solvent in resist film

The amount of solvents remaining in a resist film after prebaking was measured by the following procedure.

A resist composition having the formulation shown in Table 13 was coated onto a surface of a blank substrate and prebaked at 90° C. for 10 minutes to form a test film of 150 nm thick. The film on the surface was dissolved in acetone. The acetone was concentrated to 2 mL using nitrogen gas. After addition of cyclopentanone as the internal standard, the concentrate was analyzed by gas chromatography (GC). The measured value corresponds to the amount of solvent per blank substrate surface.

The amounts of solvents in the film as analyzed are reported in Table 14.

TABLE 13

| | | | | | Comparative |
|---|---|---|---|---|---|
| | Experiment 1 | Experiment 2 | Experiment 3 | Experiment 4 | Experiment 1 |
| | Example | Example | Example | Example | Comparative |
| Components, pbw | 3 | 22 | 23 | 24 | Example 1 |
| Polymer-2 | 80 | 80 | 80 | 80 | 80 |
| PAG-1 | 6 | 6 | 6 | 6 | 6 |
| PAG-2 | 2 | 2 | 2 | 2 | 2 |
| PGMEA | 1,400 | 1,400 | 1,400 | 1,400 | 1,400 |
| EL | 600 | 600 | 600 | 600 | 600 |
| dipropylene glycol | 160 | 80 | 240 | 320 | 0 |
| methyl ether acetate | | | | | |
| Surfactant A | 0.07 | 0.07 | 0.07 | 0.07 | 0.07 |
| N-containing compound A | 0.3 | 0.3 | 0.3 | 0.3 | 0.3 |
| N-containing compound B | 0.3 | 0.3 | 0.3 | 0.3 | 0.3 |

TABLE 14

| | | | Dipropylene glycol |
|---|---|---|---|
| | PGMEA | EL | methyl ether acetate |
| Example 3 | <1 μg | <1 μg | 26 μg |
| Example 22 | <1 μg | <1 μg | 13 μg |
| Example 23 | <1 μg | <1 μg | 51 μg |
| Example 24 | <1 μg | <1 μg | 96 μg |
| Comparative | <1 μg | <1 μg | <1 μg |
| Example 1 | | | |

As seen from the experimental results, the benefit of the invention capable of forming resist films featuring high lo in-plane uniformity and free from coarse micro-domains is correlated to the amount of residual high-boiling solvent.

Japanese Patent Application No. 2008-039730 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A chemically amplified resist composition comprising a base resin, an acid generator, and a solvent, wherein a resist film of the composition changes its solubility in a developer under the action of an acid generated by the acid generator upon exposure to high-energy radiation, wherein
the composition contains the solvent in a total amount of 1,400 to 5,000 parts by weight per 100 parts by weight of the base resin,
the solvent comprises propylene glycol monomethyl ether acetate (PGMEA) and ethyl lactate which are present in a total amount of at least 60% by weight of the total solvent weight, a weight proportion of PGMEA relative to the total solvent weight is higher than a weight proportion of any other solvent relative to the total solvent weight, a weight proportion of ethyl lactate is 10% to 40% by weight of the total solvent weight,
the solvent further comprises at least one solvent selected from the group consisting of γ-butyrolactone, alkyl acetoacetate, dipropylene glycol methyl ether acetate, dipropylene glycol butyl ether, tripropylene glycol butyl ether, ethylene carbonate, and propylene carbonate, in a proportion of 0.2% to 20% by weight of the total solvent weight.

2. The resist composition of claim 1, comprising
(A-1) a base resin having acid labile group-protected acidic functional groups which is alkali insoluble or substantially alkali insoluble, but becomes alkali soluble when the acid labile groups are eliminated,
(B) the acid generator, and
(C) a nitrogen-containing compound serving as a base, said composition being positive working.

3. The resist composition of claim 1, comprising
(A-2) a base resin which is alkali soluble, but becomes alkali insoluble in the presence of an acid catalyst and/or a combination of a crosslinker and a base resin which is alkali soluble, but becomes alkali insoluble through reaction with the crosslinker in the presence of an acid catalyst,
(B) the acid generator, and
(C) a nitrogen-containing compound serving as a base, lo said composition being negative working.

4. A process for forming a resist pattern, comprising the steps of:
forming a resist film on a processable substrate, the film forming step including coating the resist composition of claim 1 onto the substrate and prebaking the coating to remove any excess solvent therein,
exposing patternwise the resist film to high-energy radiation,
optionally post-exposure baking, and
developing the exposed resist film with a developer to form a resist pattern.

5. The process of claim 4 wherein the resist film resulting from the film forming step has a thickness of 10 nm to 150 nm.

6. The process of claim 5 wherein the resist film has a thickness of 10 nm to 100 nm.

7. The process of claim 4 wherein the resist pattern resulting from the developing step has a minimum line width of up to 50 nm.

8. The process of claim 4 wherein the processable substrate is a photomask blank.
